(19) United States
(12) Patent Application Publication
(10) Pub. No.: US 2021/0260851 A1
(43) Pub. Date: Aug. 26, 2021

(54) OPTICAL LAMINATE AND ORGANIC EL DISPLAY DEVICE

(71) Applicant: NITTO DENKO CORPORATION, Ibaraki-shi, Osaka (JP)

(72) Inventors: Hiroshi Tomohisa, Ibaraki-shi (JP); Hirofumi Katami, Ibaraki-shi (JP); Hironori Yaginuma, Ibaraki-shi (JP)

(73) Assignee: NITTO DENKO CORPORATION, Ibaraki-shi, Osaka (JP)

(21) Appl. No.: 17/252,387

(22) PCT Filed: May 20, 2019
(86) PCT No.: PCT/JP2019/019912

§ 371 Date: Dec. 15, 2020

(30) Foreign Application Priority Data
Jun. 28, 2018 (JP) 2018-123183

(51) Int. Cl. B32B 7/023; H01L 27/32; G02B 5/30; B32B 27/30; B32B 37/12; C09J 7/38; C09J 11/06; G02B 5/22; C08K 5/00

(52) U.S. Cl. CPC B32B 7/023; H01L 27/3232; G02B 5/305; B32B 27/308; B32B 37/12; B32B 2457/206; C09J 11/06; G02B 5/223; C08K 5/0041; B32B 2307/42; C09J 7/38

(57) ABSTRACT

There is provided an optical laminate that can suppress the deterioration of the optical characteristics of a retardation layer. An optical laminate according to an embodiment of the present invention includes: a UV-absorbing adhesion layer; a protective layer; a polarizer; and a retardation layer. The retardation layer contains a liquid crystal compound. The UV-absorbing adhesion layer and the polarizer are arranged on a viewer side with respect to the retardation layer, and the UV-absorbing adhesion layer contains a base polymer, a UV absorber, and a dye compound whose absorption spectrum has a maximum absorption wavelength present in a wavelength region of from 380 nm to 430 nm.

### TECHNICAL FIELD

The present invention relates to an optical laminate and an organic EL display apparatus.

### BACKGROUND ART

There has been known a technology including using a circularly polarizing plate, which is obtained by laminating a polarizer and a retardation layer, in an image display apparatus, such as an organic EL display apparatus, to suppress ambient light reflection. In addition, the use of a pressure-sensitive adhesive sheet containing a UV absorber has been proposed for the purpose of protecting a functional layer, such as a polarizer or a retardation layer, from UV light entering the image display apparatus. As such pressure-sensitive adhesive sheet, there has been known, for example, a pressure-sensitive adhesive sheet, which includes a UV-absorbing layer, has a light transmittance of 30% or less at a wavelength of 380 nm, and has a visible light transmittance of 80% or more at wavelengths longer than a wavelength of 430 nm (Patent Literature 1).

### CITATION LIST

### Patent Literature

[PTL 1] JP 2012-211305 A

### SUMMARY OF INVENTION

### Technical Problem

However, an image display apparatus using such pressure-sensitive adhesive sheet as described above involves a problem in that the optical characteristics of its retardation layer (in particular, a retardation layer containing a liquid crystal compound) may deteriorate.

The present invention has been made to solve the conventional problem, and a primary object of the present invention is to provide an optical laminate that can suppress the deterioration of the optical characteristics of a retardation layer, and an organic EL display apparatus using such optical laminate.

### Solution to Problem

An optical laminate according to an embodiment of the present invention includes: a UV-absorbing adhesion layer; a protective layer; a polarizer; and a retardation layer. The retardation layer contains a liquid crystal compound. The UV-absorbing adhesion layer and the polarizer are arranged on a viewer side with respect to the retardation layer, and the UV-absorbing adhesion layer contains a base polymer, a UV absorber, and a dye compound whose absorption spectrum has a maximum absorption wavelength present in a wavelength region of from 380 nm to 430 run.

In one embodiment of the present invention, the base polymer is a (meth)acrylic polymer.

In one embodiment of the present invention, an absorption spectrum of the UV absorber has a maximum absorption wavelength present in a wavelength region of from 300 nm to 400 nm.

In one embodiment of the present invention, the UV-absorbing adhesion layer has an average transmittance of 5% or less at a wavelength of from 300 nm to 400 nm, has an average transmittance of 30% or less at a wavelength of from 400 nm to 430 nm, has an average transmittance of 70% or more at a wavelength of from 450 nm to 500 nm, and has an average transmittance of 80% or more at a wavelength of from 500 nm to 780 nm.

In one embodiment of the present invention, the UV-absorbing adhesion layer, the protective layer, and the polarizer are arranged in the stated order.

In one embodiment of the present invention, the retardation layer has an in-plane retardation Re(550) of from 120 nm to 160 nm.

In one embodiment of the present invention, the retardation layer includes a first retardation layer and a second retardation layer. At least one of the first retardation layer or the second retardation layer contains the liquid crystal compound, and the UV-absorbing adhesion layer is arranged on the viewer side with respect to the retardation layer containing the liquid crystal compound out of the first retardation layer and the second retardation layer.

In one embodiment of the present invention, the UV-absorbing adhesion layer, the protective layer, the polarizer, the first retardation layer, and the second retardation layer are arranged in the stated order from the viewer wide. In one embodiment of the present invention, the UV-absorbing adhesion layer, the first protective layer, the polarizer, the second protective layer, the first retardation layer, and the second retardation layer are arranged in the stated order from the viewer wide. In one embodiment of the present invention, the protective layer, the polarizer, the UV-absorbing adhesion layer, the first retardation layer, and the second retardation layer are arranged in the stated order from the viewer wide. In one embodiment of the present invention, the first protective layer, the polarizer, the second protective layer, the UV-absorbing adhesion layer, the first retardation layer, and the second retardation layer are arranged in the stated order from the viewer wide.

In one embodiment of the present invention, the first retardation layer has an in-plane retardation Re(550) of from 240 nm to 320 nm.

In one embodiment of the present invention, the second retardation layer has an in-plane retardation Re(550) of from 120 nm to 160 nm.

According to another aspect of the present invention, an organic EL display apparatus is provided. The organic EL display apparatus includes the optical laminate as described above.

### Advantageous Effects of Invention

According to the present invention, the UV-absorbing adhesion layer is arranged on the viewer side with respect to the retardation layer containing the liquid crystal compound, and the UV-absorbing adhesion layer contains the dye compound. Accordingly, the optical laminate that can suppress the deterioration of the optical characteristics of the retardation layer, and the organic EL display apparatus including such optical laminate can be provided.

### BRIEF DESCRIPTION OF DRAWINGS

FIG. 1 is a schematic sectional view of an optical laminate according to one embodiment of the present invention.

FIG. 2 is a schematic sectional view of an optical laminate according to another embodiment of the present invention.

FIG. 3 is a schematic sectional view of an optical laminate according to still another embodiment of the present invention.

FIG. 4 is a schematic sectional view of an optical laminate according to still another embodiment of the present invention.

FIG. 5 is a schematic sectional view of an optical laminate according to still another embodiment of the present invention.

### DESCRIPTION OF EMBODIMENTS

Embodiments of the present invention are described below. However, the present invention is not limited to these embodiments.

(Definitions of Terms and Symbols)

The definitions of terms and symbols used herein are as described below.
(1) Refractive Indices (nx, ny, and nz)

“nx” represents a refractive index in a direction in which an in-plane refractive index is maximum (that is, slow axis direction), “ny” represents a refractive index in a direction perpendicular to the slow axis in the plane (that is, fast axis direction), and “nz” represents a refractive index in a thickness direction.
(2) In-plane Retardation (Re)

“Re(λ)” refers to an in-plane retardation measured at 23° C. with light having a wavelength of λ nm. For example, “Re (550)” refers to an in-plane retardation measured at 23° C. with light having a wavelength of 550 nm. The Re(λ) is determined from the equation “Re (λ)=(nx−ny) xd” when the thickness of a layer (film) is represented by d (nm).
(3) Thickness Direction Retardation (Rth)

“Rth (λ)” refers to a thickness direction retardation measured at 23° C. with light having a wavelength of λ nm. For example, “Rth(550)” refers to a thickness direction retardation measured at 23° C. with light having a wavelength of 550 nm. The Rth(λ) is determined from the equation “Rth (λ)=(nx−nz) xd” when the thickness of a layer (film) is represented by d (nm).

A. Overall Configuration of Optical Laminate

FIG. 1 is a schematic sectional view of an optical laminate according to one embodiment of the present invention. An optical laminate 100 includes a UV-absorbing adhesion layer 10, a protective layer 20, a polarizer 30, and a retardation layer 40. The retardation layer 40 contains a liquid crystal compound. The optical laminate 100 is typically used in an image display apparatus, such as an organic EL display apparatus. When the optical laminate 100 is used in the image display apparatus, the UV-absorbing adhesion layer 10 and the polarizer 30 are arranged on a viewer side with respect to the retardation layer 40 containing the liquid crystal compound. The UV-absorbing adhesion layer 10 contains a base polymer, a UV absorber, and a dye compound whose absorption spectrum has a maximum absorption wavelength present in a wavelength region of from 380 nm to 430 nm. The base polymer is typically a (meth) acrylic polymer. An absorption spectrum of the UV absorber typically has a maximum absorption wavelength present in a wavelength region of from 300 nm to 400 nm. It is preferred that the UV-absorbing adhesion layer 10 have an average transmittance of 5% or less at a wavelength of from 300 nm to 400 nm, have an average transmittance of 30% or less at a wavelength of from 400 nm to 430 nm, have an average transmittance of 70% or more at a wavelength of from 450 nm to 500 nm, and have an average transmittance of 80% or more at a wavelength of from 500 nm to 780 nm. In one embodiment, the UV-absorbing adhesion layer 10, the protective layer 20, and the polarizer 30 are arranged in the stated order. The retardation layer 40 preferably has an in-plane retardation Re (550) of from 120 nm to 160 nm. With the above-mentioned configuration, when the optical laminate is applied to the image display apparatus, the entry of ambient light (in particular, UV light and light having a wavelength of from 380 nm to 430 nm) into the retardation layer containing the liquid crystal compound can be suppressed. As a result, the deterioration of the optical characteristics of the retardation layer (e.g., a change in in-plane retardation thereof) can be suppressed.

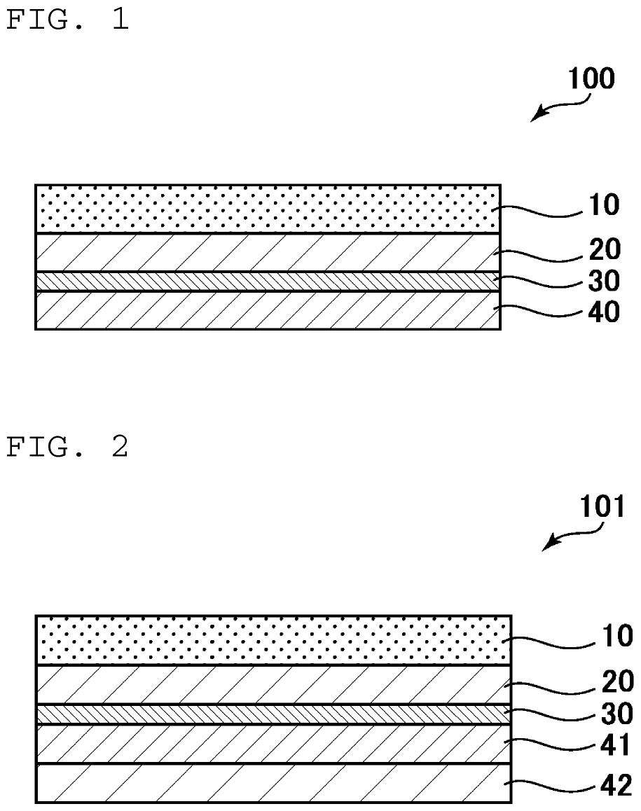

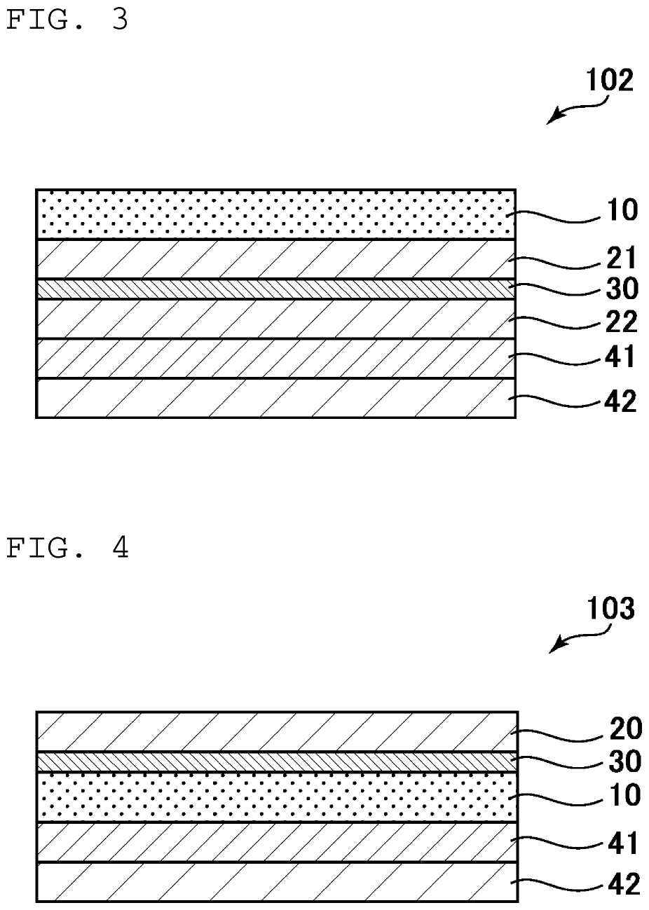

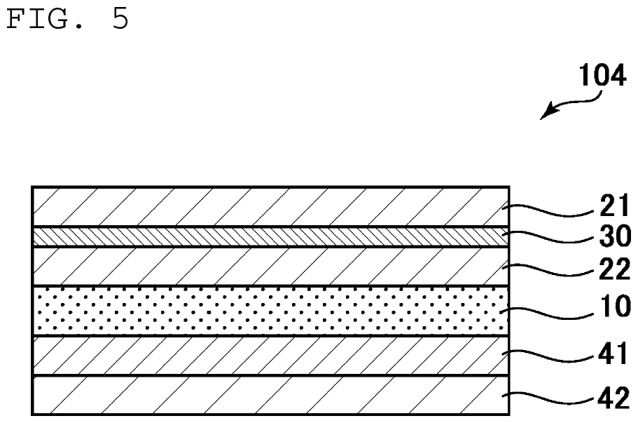

FIG. 2 is a schematic sectional view of an optical laminate according to another embodiment of the present invention. In an optical laminate 101 of this embodiment, the UV-absorbing adhesion layer 10, the protective layer 20, the polarizer 30, a first retardation layer 41, and a second retardation layer 42 are arranged in the stated order from its viewer wide. FIG. 3 is a schematic sectional view of an optical laminate according to still another embodiment of the present invention. In an optical laminate 102 of this embodiment, the UV-absorbing adhesion layer 10, a first protective layer 21, the polarizer 30, a second protective layer 22, the first retardation layer 41, and the second retardation layer 42 are arranged in the stated order from its viewer wide. FIG. 4 is a schematic sectional view of an optical laminate according to still another embodiment of the present invention. In an optical laminate 103 of this embodiment, the protective layer 20, the polarizer 30, the UV-absorbing adhesion layer 10, the first retardation layer 41, and the second retardation layer 42 are arranged in the stated order from its viewer wide. FIG. 5 is a schematic sectional view of an optical laminate according to still another embodiment of the present invention. In an optical laminate 104 of this embodiment, the first protective layer 21, the polarizer 30, the second protective layer 22, the UV-absorbing adhesion layer 10, the first retardation layer 41, and the second retardation layer 42 are arranged in the stated order from its viewer wide. As illustrated in each of FIG. 2 to FIG. 5, the optical laminate may include the first retardation layer 41 and the second retardation layer 42 as the retardation layers. In this case, at least one of the first retardation layer 41 or the second retardation layer 42 contains the liquid crystal compound. The UV-absorbing adhesion layer 10 only needs to be arranged on the viewer side with respect to the retardation layer containing the liquid crystal compound out of the first retardation layer 41 and the second retardation layer 42. For example, when the second retardation layer 42 contains the liquid crystal compound, the UV-absorbing adhesion layer 10 maybe arranged between the first retardation layer 41 and the second retardation layer 42. When the UV-absorbing adhesion layer 10 is arranged on the viewer side of the second retardation layer 42 containing the liquid crystal compound, the deterioration of the optical characteristics of the second retardation layer 42 due to the influence of ambient light (in particular, UV light and light having a wavelength of from 380 nm to 430 nm) can be suppressed. The in-plane retardation Re(550) of the first retardation layer 41 is preferably from 240 nm to 320 nm. The in-plane retardation Re(550) of the second retardation layer 42 is preferably from 120 nm to 160 nm. The respective layers in the optical laminate may be laminated via any appropriate adhesion layer (an adhesive layer or a pressure-sensitive adhesive layer). Further, a pressure-sensitive adhesive layer (or a release film with a pressure-sensitive adhesive layer) may be formed on the surface (outermost surface) of the optical laminate.

B. UV-Absorbing Adhesion Layer

As described above, the UV-absorbing adhesion layer contains a base polymer, a UV absorber, and a dye compound whose absorption spectrum has a maximum absorption wavelength present in the wavelength region of from 380 nm to 430 nm. Herein, when a plurality of absorption maxima are present in the spectral absorption spectrum of the compound in the wavelength region of from 380 nm to 430 nm, the maximum absorption wavelength means the wavelength of the absorption maximum showing the maximum absorbance out of the maxima.

The adhesive strength (strength needed for peeling) of the UV-absorbing adhesion layer is preferably from 8.0 N/20 mm to 30 N/20 mm, more preferably from 10.0 N/20 mm to 30 N/20 mm.

The UV-absorbing adhesion layer may be typically formed by applying a composition for the UV-absorbing adhesion layer onto any other layer in the optical laminate. Any appropriate method may be adopted as a method of applying the composition. Examples thereof include a roll coating method, a spin coating method, a wire bar coating method, a dip coating method, a die coating method, a curtain coating method, a spray coating method, and a knife coating method (such as a comma coating method).

B-1. Base Polymer

Any appropriate polymer may be adopted as the base polymer as long as the polymer can exhibit a required adhesive property and a required pressure-sensitive adhesive property. Specific examples of the base polymer include a (meth)acrylic polymer and a rubber-based polymer. The base polymer is preferably a (meth)acrylic polymer. The (meth)acrylic polymer maybe obtained from a partially polymerized product of a monomer component containing an alkyl (meth)acrylate and/or the monomer component.

Examples of the alkyl (meth)acrylate include alkyl (meth)acrylates each having, at its ester end, a linear or branched alkyl group having 1 to 24 carbon atoms. The alkyl (meth)acrylates may be used alone or in combination thereof. The “alkyl (meth)acrylate” refers to an alkyl acrylate and/or an alkyl methacrylate, and “(meth)” in the present invention has a similar meaning.

Examples of the alkyl (meth) acrylate may include the linear or branched alkyl (meth) acrylates each having 1 to 24 carbon atoms described in the foregoing. Of those, an alkyl (meth) acrylate having 1 to 9 carbon atoms is preferred, an alkyl (meth)acrylate having 4 to 9 carbon atoms is more preferred, and a branched alkyl (meth)acrylate having 4 to 9 carbon atoms is still more preferred. Any such alkyl (meth) acrylate is preferred because a balance between pressure-sensitive adhesive characteristics is easily achieved.

The alkyl (meth)acrylate having, at its ester end, an alkyl group having 1 to 24 carbon atoms accounts for preferably 40 wt % or more, more preferably 50 wt % or more, still more preferably 60 wt % or more with respect to the total amount of monofunctional monomer components for forming the (meth)acrylic polymer.

The monomer components may include, as a monofunctional monomer component, a copolymerizable monomer other than the alkyl (meth)acrylate. The copolymerizable monomer may be used as the balance of the monomer components excluding the alkyl (meth) acrylate. For example, a cyclic nitrogen-containing monomer may be incorporated as the copolymerizable monomer. As the cyclic nitrogen-containing monomer, there may be used, without any particular limitation, a monomer that has a polymerizable functional group having an unsaturated double bond, such as a (meth)acryloyl group or a vinyl group, and that has a cyclic nitrogen structure. The cyclic nitrogen structure preferably has a nitrogen atom in a cyclic structure. The content of the cyclic nitrogen-containing monomer is preferably from 0.5 wt % to 50 wt %, more preferably from 0.5 wt % to 40 wt %, still more preferably from 0.5 wt % to 30 wt % with respect to the total amount of the monofunctional monomer components for forming the (meth)acrylic polymer.

The monomer components may include, as a monofunctional monomer component, a hydroxyl group-containing monomer. A monomer having a polymerizable functional group having an unsaturated double bond, such as a (meth)acryloyl group or a vinyl group, and having a hydroxyl group may be used as the hydroxyl group-containing monomer without any particular limitation. The content of the hydroxyl group-containing monomer is preferably 1 wt % or more, more preferably 2 wt % or more, still more preferably 3 wt % or more with respect to the total amount of the monofunctional monomer components for forming the (meth)acrylic polymer from the viewpoint of improving the adhesive strength and cohesive strength of the UV-absorbing adhesion layer. Meanwhile, the upper limit of the content of the hydroxyl group-containing monomer is preferably 30 wt %, more preferably 27 wt %, still more preferably 25 wt % with respect to the total amount of the monofunctional monomer components for forming the (meth)acrylic polymer. When the content of the hydroxyl group-containing monomer becomes excessively large, the pressure-sensitive adhesive layer may become harder to be reduced in adhesive strength. In addition, the pressure-sensitive adhesive may be excessively increased in viscosity, or may gel.

The monomer components for forming the (meth)acrylic polymer may include, as a monofunctional monomer, any other functional group-containing monomer. Examples of such monomer include a carboxyl group-containing monomer and a monomer having acyclic ether group. The content of the carboxyl group-containing monomer or the monomer having a cyclic ether group is preferably 30 wt % or less, more preferably 27 wt % or less, still more preferably 25 wt % or less with respect to the total amount of the monofunctional monomer components for forming the (meth)acrylic polymer.

The copolymerizable monomer of the monomer components for forming the (meth)acrylic polymer is, for example, an alkyl (meth)acrylate represented by CH₂=C (R¹)COOR² (where R¹ represents hydrogen or a methyl group, and R² represents a substituted alkyl group having 1 to 3 carbon atoms, or a cycloalkyl group). The substituent of the substituted alkyl group having 1 to 3 carbon atoms that is represented by R² is preferably an aryl group having 6 to 8 carbon atoms, or an aryloxy group having 6 to 8 carbon atoms. The aryl group is not limited, but is preferably a phenyl group. Examples of such monomer represented by CH₂=C(R¹)COOR² include phenoxyethyl (meth)acrylate, benzyl (meth)acrylate, cyclohexyl (meth)acrylate, 3,3,5-trimethylcyclohexyl (meth)acrylate, and isobornyl (meth)acrylate. Those monomers may be used alone or in combination thereof. The content of the (meth) acrylate represented by CH₂=C(R¹)COOR² is preferably 50 wt % or less, more preferably 45 wt % or less, still more preferably 40 wt % or less, particularly preferably 35 wt % or less with respect to the total amount of the monofunctional monomer components for forming the (meth)acrylic polymer.

In addition to the above-mentioned monofunctional monomers, any appropriate polyfunctional monomer maybe incorporated into the monomer components for forming the (meth)acrylic polymer as required for adjusting the cohesive strength of the pressure-sensitive adhesive.

Any appropriate method may be adopted as a method of producing the (meth)acrylic polymer, and examples thereof include various kinds of radical polymerization including: solution polymerization; radiation polymerization, such as ultraviolet (UV) polymerization; bulk polymerization; and emulsion polymerization. In addition, the (meth)acrylic polymer to be obtained may be any of a random copolymer, a block copolymer, a graft copolymer, and the like.

When the (meth)acrylic polymer is produced by radical polymerization, the polymerization maybe performed by appropriately adding, to the monomer components, a polymerization initiator, a chain transfer agent, an emulsifying agent, or the like to be used in the radical polymerization. The polymerization initiator, the chain transfer agent, the emulsifying agent, or the like to be used in the radical polymerization is not particularly limited, and may be appropriately selected and used. The weight-average molecular weight of the (meth) acrylic polymer may be controlled by the usage amount of the polymerization initiator or the chain transfer agent, and reaction conditions, and is appropriately adjusted in accordance with the kind thereof.

When the (meth)acrylic polymer is produced by the radiation polymerization, the polymer maybe produced by irradiating the monomer components with a radiation such as an electron beam or UV light (UV) to polymerize the components. Of those, UV polymerization is preferred. When the UV polymerization is performed, a photopolymerization initiator is preferably incorporated into the monomer components because of, for example, an advantage in that a polymerization time can be shortened.

The photopolymerization initiator, which is not particularly limited, is preferably a photo polymerization initiator (A) having an absorption band at a wavelength of 400 nm or more. Examples of such photopolymerization initiator (A) may include bis(2,4,6-trimethylbenzoyl)-phenylphosphine oxide (Irgacure 819, manufactured by BASF), and 2,4,6-trimethylbenzoyl-diphenyl-phosphine oxide (LUCIRIN TPO, manufactured by BASF).

A photopolymerization initiator (B) having an absorption band at a wavelength of less than 400 nm maybe incorporated into the photopolymerization initiator. The photopolymerization initiator (B) is not particularly limited as long as the initiator generates a radical with UV light to initiate photopolymerization, and has an absorption band at a wavelength of less than 400 nm, and any one of photopolymerization initiators to be typically used may be suitably used. For example, there may be used a benzoin ether-based photopolymerization initiator, an acetophenone-based photopolymerization initiator, an α-ketol-based photopolymerization initiator, a photoactive oxime-based photopolymerization initiator, a benzoin-based photopolymerization initiator, a benzyl-based photopolymerization initiator, a benzophenone-based photopolymerization initiator, a ketal-based photopolymerization initiator, a thioxanthone-based photopolymerization initiator, and an acylphosphine oxide-based photopolymerization initiator.

When the monomer components are subjected to the UV polymerization, the following is preferably adopted: after the photopolymerization initiator (B) has been added in advance to the monomer components, and UV irradiation has been performed to partially polymerize the monomer components, the photopolymerization initiator (A), the UV absorber, and the dye compound are added to the resultant partially polymerized product (prepolymer composition), and the mixture is subjected to the UV polymerization. At the time of the addition of the photopolymerization initiator (A) to the partially polymerized product (prepolymer composition) of the monomer components obtained by partially polymerizing the components through the UV irradiation, the photopolymerization initiator is preferably added after having been dissolved in a monomer.

B-2. UV Absorber

Any appropriate UV absorber may be used as the UV absorber. Specific examples thereof may include a triazine-based UV absorber, a benzotriazole-based UV absorber, a benzophenone-based UV absorber, an oxybenzophenone-based UV absorber, a salicylic acid ester-based UV absorber, and a cyanoacrylate-based UV absorber. Those UV absorbers may be used alone or in combination thereof. Of those, the triazine-based UV absorber or the benzotriazole-based UV absorber is preferred, and at least one kind of UV absorber selected from the group consisting of a triazine-based UV absorber having two or less hydroxyl groups in a molecule thereof and a benzotriazole-based UV absorber having one benzotriazole skeleton in a molecule thereof is more preferred because the absorber has satisfactory solubility in a monomer to be used in the formation of an acrylic pressure-sensitive adhesive composition, and has a high UV-absorbing ability at a wavelength near 380 nm. The UV absorbers may be used alone or as a mixture thereof.

The maximum absorption wavelength of the absorption spectrum of the UV absorber is preferably present in the wavelength region of from 300 nm to 400 nm, and is more preferably present in the wavelength region of from 320 nm to 380 nm. The maximum absorption wavelength may be measured with a UV-visible spectrophotometer.

B-3. Dye Compound

As described above, the maximum absorption wavelength of the absorption spectrum of the dye compound is present in the wavelength region of from 380 nm to 430 nm. The maximum absorption wavelength of the absorption spectrum of the dye compound is preferably present in the wavelength region of from 380 nm to 420 nm. When such dye compound and UV absorber are used in combination, the UV-absorbing adhesion layer can sufficiently absorb light in a region (corresponding to a wavelength of from 380 nm to 430 nm) that does not affect the light emission of an organic EL element, and can sufficiently transmit light in the light-emitting region of the organic EL element (corresponding to a wavelength longer than 430 nm). As a result, the deterioration of the optical characteristics of the retardation layer can be suppressed.

The half-width of the dye compound is preferably 80 nm or less, more preferably from 5 nm to 70 nm, still more preferably from 10 nm to 60 nm. With this, the UV-absorbing adhesion layer can sufficiently transmit light having a wavelength longer than 430 nm while sufficiently absorbing light in the region that does not affect the light emission of an organic EL element. The half-width of the dye compound may be measured from a transmission/absorption spectrum of a solution of the dye compound with a UV-visible spectrophotometer (U-4100, manufactured by Hitachi High-Tech Science Corporation) under the conditions as indicated below. Typically, on the basis of an optical spectrum measured at such an adjusted concentration that the absorbance at the maximum absorption wavelength is 1.0, a distance (full width at half maximum) in wavelength between two points corresponding to 50% of a peak value is adopted as the half-width of the dye compound.

### (Measurement Conditions)

Solvent: toluene or chloroform

Cell: quartz cell

Optical path length: 10 mm

The dye compound only needs to be a compound having, in an absorption spectrum thereof, a maximum absorption wavelength in the above-mentioned wavelength region, and its structure and the like are not particularly limited. Examples of the dye compound may include an organic dye compound and an inorganic dye compound.

Of those, an organic dye compound is preferred from the viewpoints of dispersibility in a resin component, such as the base polymer, and the maintenance of transparency.

Examples of the organic dye compound may include an azomethine-based compound, an indole-based compound, a cinnamic acid-based compound, a pyrimidine-based compound, and a porphyrin-based compound.

A commercial compound may be suitably used as the organic dye compound. Specifically, the indole-based compound may be, for example, BONASORB UA3911 (product name, maximum absorption wavelength of its absorption spectrum: 398 nm, half-width: 48 nm, manufactured by Orient Chemical Industries Co., Ltd.) or BONASORB UA3912 (product name, maximum absorption wavelength of its absorption spectrum: 386 nm, half-width: 53 nm, manufactured by Orient Chemical Industries Co., Ltd.), the cinnamic acid-based compound may be, for example, SOM-5-0106 (product name, maximum absorption wavelength of its absorption spectrum: 416 nm, half-width: 50 nm, manufactured by Orient Chemical Industries Co., Ltd.), and the porphyrin-based compound may be, for example, FDB-001 (product name, maximum absorption wavelength of its absorption spectrum: 420 nm, half-width: 14 nm, manufactured by Yamada Chemical Co., Ltd.).

Although the dye compounds may be used alone or as a mixture thereof, the entire content of the compound is preferably from 0.01 part by weight to 10 parts by weight, more preferably from about 0.02 part by weight to about 5 parts by weight with respect to 100 parts by weight of the monofunctional monomer components for forming the (meth)acrylic polymer. When the addition amount of the dye compound is set within the ranges, the UV-absorbing adhesion layer can sufficiently absorb light in the region that does not affect the light emission of an organic EL element, and hence the deterioration of the optical characteristics of the retardation layer can be suppressed.

B-4. Other Components

The UV-absorbing adhesion layer and/or the composition for the UV-absorbing adhesion layer may contain any other component, such as a silane coupling agent or a cross-linking agent, as required.

As the silane coupling agent, there may be used, for example: epoxy group-containing silane coupling agents, such as 3-glycidoxypropyltrimethoxysilane, 3-glycidoxypropyltriethoxysilane, 3-glycidoxypropylmethyldiethoxysilane, and 2-(3,4-epoxycyclohexyl)ethyltrimethoxysilane; amino group-containing silane coupling agents, such as 3-aminopropyltrimethoxysilane, N-2-(aminoethyl)-3-aminopropylmethyldimethoxysilane, 3-triethoxysilyl-N-(1,3-dimethylbutylidene)propylamine, and N-phenyl-y-aminopropyltrimethoxysilane; (meth)acrylic group-containing silane coupling agents, such as 3-acryloxypropyltrimethoxysilane, and 3-methacryloxypropyltriethoxysilane; and isocyanate group-containing silane coupling agents, such as 3 -isocyanatopropyltriethoxysilane. The content of the silane coupling agent is preferably 1 part by weight or less, more preferably from 0.01 part by weight to 1 part by weight, still more preferably from 0.02 part by weight to 0.6 part by weight with respect to 100 parts by weight of the monofunctional monomer components for forming the (meth)acrylic polymer.

As the cross-linking agent, for example, an isocyanate-based cross-linking agent, an epoxy-based cross-linking agent, a silicone-based cross-linking agent, an oxazoline-based cross-linking agent, an aziridine-based cross-linking agent, a silane-based cross-linking agent, an alkyl etherified melamine-based cross-linking agent, a metal chelate-based cross-linking agent, or a peroxide maybe used. The cross-linking agents may be used alone or in combination thereof. Of those, an isocyanate-based cross-linking agent is preferably used. The content of the cross-linking agent is preferably 5 parts by weight or less, more preferably from 0.01 part by weight to 5 parts by weight, still more preferably from 0.01 part by weight to 4 parts by weight, particularly preferably from 0.02 part by weight to 3 parts by weight with respect to 100 parts by weight of the monofunctional monomer components for forming the (meth)acrylic polymer.

The isocyanate-based cross-linking agent refers to a compound having two or more isocyanate groups (including an isocyanate reproduction-type functional group obtained by temporarily protecting an isocyanate group through an approach such as a blocking agent or oligomerization) in a molecule thereof. Examples of the isocyanate-based cross-linking agent include: aromatic isocyanates, such as tolylene diisocyanate and xylene diisocyanate; alicyclic isocyanates, such as isophorone diisocyanate; and aliphatic isocyanates, such as hexamethylene diisocyanate. More specific examples thereof include: lower aliphatic polyisocyanates, such as butylene diisocyanate and hexamethylene diisocyanate; alicyclic isocyanates, such as cyclopentylene diisocyanate, cyclohexylene diisocyanate, and isophorone diisocyanate; aromatic diisocyanates, such as 2,4-tolylene diisocyanate, 4,4′-diphenylmethane diisocyanate, xylylene diisocyanate, and polymethylene polyphenyl isocyanate; isocyanate adducts, such as a trimethylolpropane/tolylene di isocyanate trimer adduct (product name: Coronate L, manufactured by Nippon Polyurethane Industry Co., Ltd.), a trimethylolpropane/hexamethylene diisocyanate trimer adduct (product name: Coronate HL, manufactured by Nippon Polyurethane Industry Co., Ltd.), and an isocyanurate form of hexamethylene diisocyanate (product name: Coronate HX, manufactured by Nippon Polyurethane Industry Co., Ltd.), a trimethylolpropane adduct of xylylene diisocyanate (product name: D110N, manufactured by Mitsui Chemicals, Inc.), and a trimethylolpropane adduct of hexamethylene di isocyanate (product name : D160N, manufactured by Mitsui Chemicals, Inc.); and polyether polyisocyanate, polyester polyisocyanate, adducts of those compounds and various polyols, and polyisocyanates multifunctionalized by, for example, an isocyanurate bond, a biuret bond, and an allophanate bond.

C. Polarizer

Any appropriate polarizer may be adopted as the polarizer. For example, a resin film for forming the polarizer may be a single-layer resin film or a laminate of two or more layers.

Specific examples of the polarizer formed of a single-layer resin film include: a polarizer obtained by subjecting a hydrophilic polymer film, such as a polyvinyl alcohol (PVA) -based film, a partially formalized PVA-based film, or an ethylene-vinyl acetate copolymer-based partially saponified film, to dyeing treatment with a dichroic substance, such as iodine or a dichroic dye, and stretching treatment; and a polyene-based alignment film, such as a dehydration-treated product of PVA or a dehydrochlorination-treated product of polyvinyl chloride. A polarizer obtained by dyeing the PVA-based film with iodine and uniaxially stretching the resultant is preferably used because the polarizer is excellent in optical characteristics.

The dyeing with iodine is performed by, for example, immersing the PVA-based film in an aqueous solution of iodine. The stretching ratio of the uniaxial stretching is preferably from 3 times to 7 times. The stretching may be performed after the dyeing treatment, or may be performed while the dyeing is performed. In addition, the dyeing may be performed after the stretching has been performed. The PVA-based film is subjected to swelling treatment, cross-linking treatment, washing treatment, drying treatment, or the like as required. For example, when the PVA-based film is immersed in water to be washed with water before the dyeing, contamination or an antiblocking agent on the surface of the PVA-based film can be washed off. In addition, the PVA-based film is swollen and hence dyeing unevenness or the like can be prevented.

A specific example of the polarizer obtained by using a laminate is a polarizer obtained by using a laminate of a resin substrate and a PVA-based resin layer (PVA-based resin film) laminated on the resin substrate or a laminate of a resin substrate and a PVA-based resin layer formed on the resin substrate through application. The polarizer obtained by using the laminate of the resin substrate and the PVA-based resin layer formed on the resin substrate through application may be produced, for example, by: applying a PVA-based resin solution to the resin substrate; drying the solution to form the PVA-based resin layer on the resin substrate, to thereby provide the laminate of the resin substrate and the PVA-based resin layer; and stretching and dyeing the laminate to turn the PVA-based resin layer into the polarizer. In this embodiment, the stretching typically includes stretching of the laminate under a state in which the laminate is immersed in an aqueous solution of boric acid. Further, the stretching may further include in-air stretching of the laminate at high temperature (e.g., 95° C. or more) before the stretching in the aqueous solution of boric acid as required. The resultant laminate of the resin substrate and the polarizer may be used as it is (i.e., the resin substrate may be used as a protective layer for the polarizer). Alternatively, a product obtained as described below may be used: the resin substrate is peeled from the laminate of the resin substrate and the polarizer, and any appropriate protective layer in accordance with purposes is laminated on the peeling surface. Details of such method of producing the polarizer are described in, for example, JP 2012-73580 A, the description of which is incorporated herein by reference in its entirety.

The thickness of the polarizer is, for example, from 1 μm to 80 μm. In one embodiment, the thickness of the polarizer is preferably from 1 μm to 15 μm, more preferably from 3 μm to 10 μm, particularly preferably from 3 μm to 8 μm. When the thickness of the polarizer falls within such ranges, curling at the time of heating can be satisfactorily suppressed, and satisfactory appearance durability at the time of heating is obtained.

The polarizer preferably shows absorption dichroism at any wavelength in the wavelength range of from 380 nm to 780 nm. The single layer transmittance of the polarizer is from 35.0% to 46.0%, preferably from 37.0% to 46.0%. The polarization degree of the polarizer is preferably 97.0% or more, more preferably 99.0% or more, still more preferably 99.9% or more.

The single layer transmittance and the polarization degree may be measured with a spectrophotometer. A specific method of measuring the polarization degree is as follows: the parallel transmittance (H₀) and cross transmittance (H₉₀) of the polarizer are measured, and the polarization degree can be determined from the equation “polarization degree (%)={(H₀−H₉₀)/(H₀+H₉₀)}^{1/2}×100”. The parallel transmittance (H₀) is the value of the transmittance of a parallel laminated polarizer produced by superimposing two polarizers of the same kind on each other so that their absorption axes may be parallel to each other. In addition, the cross transmittance (H₉₀) is the value of the transmittance of a perpendicular laminated polarizer produced by superimposing two polarizers of the same kind on each other so that their absorption axes maybe perpendicular to each other. Those transmittances are Y values subjected to visibility correction by the two-degree field of view (C light source) of JIS Z 8701-1982.

D. Protective Layer

The protective layer, the first protective layer, and the second protective layer are each formed of any appropriate protective film that may be used as a film for protecting the polarizer. As a material serving as a main component of the protective film, there are specifically given, for example, cellulose-based resins, such as triacetylcellulose (TAC), and transparent resins, such as polyester-based, polyvinyl alcohol-based, polycarbonate-based, polyamide-based, polyimide-based, polyether sulfone-based, polysulfone-based, polystyrene-based, polynorbornene-based, polyolefin-based, (meth) acryl ic, and acetate-based resins. There are also given, for example, thermosetting resins or UV-curable resins, such as (meth)acrylic, urethane-based, (meth)acrylic urethane-based, epoxy-based, and silicone-based resins. There are also given, for example, glassy polymers, such as a siloxane-based polymer. In addition, a polymer film described in JP 2001-343529 A (WO 01/37007 A1) may be used. For example, a resin composition containing a thermoplastic resin having a substituted or unsubstituted imide group on a side chain thereof, and a thermoplastic resin having a substituted or unsubstituted phenyl group and a nitrile group on side chains thereof may be used as a material for the film, and the composition is, for example, a resin composition containing an alternating copolymer formed of isobutene and N-methylmaleimide, and an acrylonitrile-styrene copolymer. The polymer film may be, for example, an extrudate of the resin composition.

The thickness of the protective film is preferably from 10 μm to 100 μm. The protective film may be laminated on the polarizer via an adhesion layer (specifically an adhesive layer or a pressure-sensitive adhesive layer), or may be laminated so as to be brought into close contact with the polarizer (without via the adhesion layer). The adhesive layer is formed from any appropriate adhesive. The adhesive is, for example, a water-soluble adhesive containing a polyvinyl alcohol-based resin as a main component. The water-soluble adhesive containing the polyvinyl alcohol-based resin as a main component may preferably further contain metal compound colloid. The metal compound colloid may be a product obtained by dispersing metal compound fine particles in a dispersion medium, and may be a product that is electrostatically stabilized as a result of mutual repulsion between the same charges of the fine particles to permanently have stability. The average particle diameter of the fine particles for forming the metal compound colloid may be any appropriate value as long as the optical characteristics of the polarizer, such as a polarization characteristic, are not adversely affected. The average particle diameter is preferably from 1 nm to 100 nm, more preferably from 1 nm to 50 nm. This is because the fine particles can be uniformly dispersed in the adhesive layer, and hence an adhesive property is secured and a knick can be suppressed. The term “knick” refers to a local uneven defect occurring at an interface between the polarizer and the protective film. The pressure-sensitive adhesive layer includes any appropriate pressure-sensitive adhesive.

E. Retardation Layer

As described above, the retardation layer contains the liquid crystal compound. When the optical laminate includes a plurality of retardation layers, at least one of the retardation layers contains the liquid crystal compound.

In a first embodiment, the optical laminate includes one retardation layer. The in-plane retardation Re (550) of the retardation layer is preferably from 120 nm to 160 nm, more preferably from 130 nm to 150 nm. Therefore, the retardation layer of this embodiment may function as a λ/4 plate. An angle formed by the absorption axis of the polarizer and the slow axis of the retardation layer is preferably from 39° to 51°, more preferably from 42° to 48°, particularly preferably about 45°. With this, the polarizer and the retardation layer can function as a circularly polarizing plate.

In a second embodiment, the optical laminate includes the first retardation layer and the second retardation layer. The in-plane retardation Re(550) of the first retardation layer is preferably from 240 nm to 320 nm, more preferably from 260 nm to 300 nm. The in-plane retardation Re (550) of the second retardation layer is preferably from 120 nm to 160 nm, more preferably from 130 nm to 150 nm. Therefore, the first retardation layer of this embodiment may function as a λ/2 plate, and the second retardation layer thereof may function as a λ/4 plate. An angle formed by the absorption axis of the polarizer and the slow axis of the first retardation layer is preferably from 5° to 25°, more preferably from 10° to 20°, particularly preferably about 15°. An angle formed by the absorption axis of the polarizer and the slow axis of the second retardation layer is preferably from 65° to 85°, more preferably from 70° to 80°, particularly preferably about 75°. At least one of the first retardation layer or the second retardation layer contains the liquid crystal compound. One of the first retardation layer and the second retardation layer maybe a polymer film free of any liquid crystal compound.

In a third embodiment, the in-plane retardation Re (550) of the first retardation layer is preferably from 120 nm to 160 nm, more preferably from 130 nm to 150 nm. The refractive index ellipsoid of the second retardation layer satisfies a relationship of nz>nx=ny. Therefore, the first retardation layer of this embodiment may function as a λ/4 plate, and the second retardation layer thereof may function as a so-called positive C-plate. An angle formed by the absorption axis of the polarizer and the slow axis of the first retardation layer is preferably from 39° to 51°, more preferably from 42° to 48°, particularly preferably about 45°. At least one of the first retardation layer or the second retardation layer contains the liquid crystal compound. One of the first retardation layer and the second retardation layer maybe a stretched body of a polymer film free of any liquid crystal compound.

Detailed configurations of the respective retardation layers of the respective embodiments, that is, the first embodiment to the third embodiment are described below.

E-1. Retardation Layer of First Embodiment

The retardation layer may include an alignment fixed layer of a liquid crystal compound. When the liquid crystal compound is used, the difference between nx and ny of the retardation layer to be obtained can be markedly increased as compared to a non-liquid crystal material, and hence the thickness of the retardation layer required for obtaining a desired in-plane retardation can be markedly reduced. As a result, further thinning of the optical laminate (finally, the image display apparatus) can be achieved. The term “alignment fixed layer” as used herein refers to a layer in which the liquid crystal compound is aligned in a predetermined direction and its alignment state is fixed. In this embodiment, a rod-shaped liquid crystal compound is typically aligned in a state of being aligned in the slow axis direction of the retardation layer (homogeneous alignment). An example of the liquid crystal compound is a liquid crystal compound whose liquid crystal phase is a nematic phase (nematic liquid crystal). As such liquid crystal compound, for example, a liquid crystal polymer or a liquid crystal monomer maybe used. The expression mechanism of the liquid crystallinity of the liquid crystal compound may be lyotropic or thermotropic. The liquid crystal polymer and the liquid crystal monomer may be used alone or in combination thereof.

When the liquid crystal compound is the liquid crystal monomer, the liquid crystal monomer is preferably a polymerizable monomer or a cross-linkable monomer. This is because the alignment state of the liquid crystal monomer can be fixed by polymerizing or cross-linking the liquid crystal monomer. After the alignment of the liquid crystal monomer, for example, when molecules of the liquid crystal monomer are polymerized or cross-linked with each other, the alignment state can be fixed as a result. In this case, a polymer is formed through the polymerization and a three-dimensional network structure is formed through the cross-linking, and the polymer and the structure are non-liquid crystalline. Therefore, the formed retardation layer does not undergo, for example, a transition caused by a temperature change to a liquid crystal phase, a glass phase, or a crystal phase, which is peculiar to a liquid crystalline compound. As a result, the retardation layer becomes a retardation layer that is extremely excellent in stability without being affected by a temperature change.

The temperature range in which the liquid crystal monomer shows liquid crystallinity varies depending on its kind. Specifically, the temperature range is preferably from 40° C. to 120° C., more preferably from 50° C. to 100° C., most preferably from 60° C. to 90° C.

Any appropriate liquid crystal monomer may be adopted as the liquid crystal monomer. For example, a polymerizable mesogenic compound and the like described in JP 2002-533742 A (WO 00/37585 A1), EP 358208 B1 (U.S. Pat. No. 5,211,877 A), EP 66137 B1 (U.S. Pat. No. 4,388,453 A), WO 93/22397 A1, EP 0261712 A1, DE 19504224 A1, DE 4408171 A1, GB 2280445 B, and the like may be used. Specific examples of such polymerizable mesogenic compound include a product available under the product name LC242 from. BASF SE, a product available under the product name E7 from Merck KGaA, and a product available under the product name LC-Sillicon-CC3767 from Wacker Chemie AG. The liquid crystal monomer is preferably, for example, a nematic liquid crystal monomer.

The alignment fixed layer of a liquid crystal compound maybe formed by: subjecting the surface of a predetermined substrate to alignment treatment; applying an application liquid containing a liquid crystal compound onto the surface; aligning the liquid crystal compound in a direction corresponding to the alignment treatment; and fixing the alignment state. In one embodiment, the substrate is any appropriate resin film, and the alignment fixed layer formed on the substrate may be transferred onto the surface of the polarizer.

Any appropriate alignment treatment may be adopted as the alignment treatment. Specific examples thereof include mechanical alignment treatment, physical alignment treatment, and chemical alignment treatment. Specific examples of the mechanical alignment treatment include rubbing treatment and stretching treatment. Specific examples of the physical alignment treatment include magnetic field alignment treatment and electric field alignment treatment. Specific examples of the chemical alignment treatment include an oblique deposition method and photoalignment treatment. Any appropriate conditions may be adopted as treatment conditions for the various alignment treatments in accordance with purposes.

The alignment of the liquid crystal compound is performed through treatment at a temperature at which the liquid crystal compound shows a liquid crystal phase depending on the kind of the liquid crystal compound. When the treatment at such temperature is performed, the liquid crystal compound adopts a liquid crystal state, and the liquid crystal compound is aligned depending on the alignment treatment direction of the surface of the substrate.

In one embodiment, the fixation of the alignment state is performed by cooling the liquid crystal compound aligned as described above. When the liquid crystal compound is the polymerizable monomer or the cross-linkable monomer, the fixation of the alignment state is performed by subjecting the liquid crystal compound aligned as described above to polymerization treatment or cross-linking treatment.

Specific examples of the liquid crystal compound and details about the method of forming the alignment fixed layer are described in JP 2006-163343 A, the description of which is incorporated herein by reference.

The thickness of the retardation layer may be set so that a desired in-plane retardation maybe obtained, and the thickness is preferably from 1 μm to 10 μm, more preferably from 1 μm to 6 μm.

E-2. Retardation Layers of Second Embodiment

In this embodiment, as described above, the in-plane retardation Re(550) of the first retardation layer is preferably from 240 nm to 320 nm, and the in-plane retardation Re(550) of the second retardation layer is preferably from 120 nm to 160 nm.

E-2-1. First Retardation Layer

The first retardation layer may include an alignment fixed layer of a liquid crystalline composition containing a discotic liquid crystal compound aligned in a substantially vertical manner. The term “discotic liquid crystal compound” as used herein refers to a compound having a disc-shaped mesogen group in its molecular structure and having 2 to 8 side chains radially bonded to the mesogen group via an ether bond or an ester bond. The mesogen group is, for example, a group having a structure illustrated in FIG. 1 on P. 22 of “Liquid Crystal Dictionary” (Baifukan Co., Ltd.). Specific examples thereof include benzene, triphenylene, truxene, pyran, rufigallol, porphyrin, and a metal complex. The discotic liquid crystal compound aligned in a substantially vertical manner ideally has an optical axis in one direction in a film surface. The term “discotic liquid crystal compound aligned in a substantially vertical manner” refers to a discotic liquid crystal compound in a state in which its disc surface is vertical to a film plane and its optical axis is parallel to the film plane.

The liquid crystalline composition containing the discotic liquid crystal compound is not particularly limited as long as the composition contains the discotic liquid crystal compound to show liquid crystallinity. The content of the discotic liquid crystal compound in the liquid crystalline composition is preferably 40 parts by weight or more and less than 100 parts by weight, more preferably 50 parts by weight or more and less than 100 parts by weight, most preferably 70 parts by weight or more and less than 100 parts by weight with respect to 100 parts by weight of the total solid content of the liquid crystalline composition.

A retardation film formed of the alignment fixed layer of the liquid crystalline composition containing the discotic liquid crystal compound aligned in a substantially vertical manner may be obtained by a method described in JP 2001-56411 A. When the retardation film formed of the alignment fixed layer of the liquid crystalline composition containing the discotic liquid crystal compound aligned in a substantially vertical manner is applied in one direction, a direction in which a refractive index in the film plane increases (slow axis direction) occurs in a direction substantially perpendicular to the application direction. Accordingly, a roll-shaped retardation film having a slow axis in a direction perpendicular to its lengthwise direction can be produced by continuous application without particular performance of any subsequent stretching or shrinking treatment. Roll-to-roll operation can be performed in the lamination of the roll-shaped retardation film having the slow axis in the direction perpendicular to its lengthwise direction with any other layer.

The thickness of the first retardation layer may be set so that a desired in-plane retardation may be obtained, and the thickness is preferably from 1 μm to 20 μm, more preferably from 1 μm to 12 μm.

E-2-2. Second Retardation Layer

When the second retardation layer of this embodiment contains the liquid crystal compound, the layer may be formed by using, for example, the material and the method described in the section E-1. When the second retardation layer is free of any liquid crystal compound, the layer may be formed by using a material and a method described in the section E-2-3 to be described below.

E-2-3. Others

In this embodiment, one of the first retardation layer and the second retardation layer may be a stretched body of a polymer film free of any liquid crystal compound. In this case, the retardation layer may include any appropriate resin film. Typical examples of such resin include a polycarbonate-based resin, a cyclic olefin-based resin, a cellulose-based resin, a polyester-based resin, a polyvinyl alcohol-based resin, a polyamide-based resin, a polyimide-based resin, a polyether-based resin, a polystyrene-based resin, and an acrylic resin.

Any appropriate polycarbonate-based resin may be used as the polycarbonate-based resin as long as the effects of the present invention are exhibited. The polycarbonate-based resin preferably has a structural unit derived from a fluorene-based dihydroxy compound, a structural unit derived from an isosorbide-based dihydroxy compound, and a structural unit derived from at least one dihydroxy compound selected from the group consisting of an alicyclic diol, an alicyclic dimethanol, a di, tri, or polyethylene glycol, and an alkylene glycol or a spiroglycol. The polycarbonate-based resin preferably has a structural unit derived from a fluorene-based dihydroxy compound, a structural unit derived from an isosorbide-based dihydroxy compound, and a structural unit derived from an alicyclic dimethanol and/or a structural unit derived from a di, tri, or polyethylene glycol, and more preferably has a structural unit derived from a fluorene-based dihydroxy compound, a structural unit derived from an isosorbide-based dihydroxy compound, and a structural unit derived from a di, tri, or polyethylene glycol. The polycarbonate-based resin may have a structural unit derived from any other dihydroxy compound as required. Details about the polycarbonate-based resin that maybe suitably used in the present invention are described, for example, in JP 2014-10291 A or JP 2014-26266 A, the description of which is incorporated herein by reference.

The cyclic olefin-based resin is a generic term for resins each polymerized by using a cyclic olefin as a polymerization unit, and examples thereof include resins described in JP 01-240517 A, JP 03-14882 A, and JP 03-122137 A. Specific examples thereof include: a ring-opened (co) polymer of the cyclic olefin, an addition polymer of the cyclic olefin, a copolymer (typically a random copolymer) of the cyclic olefin and an α-olefin, such as ethylene or propylene, and graft-modified products obtained by modifying those polymers with unsaturated carboxylic acids or derivatives thereof; and hydrogenated products thereof. A specific example of the cyclic olefin is a norbornene-based monomer. Examples of the norbornene-based monomer include monomers described in JP 2015-210459 A and the like. The cyclic olefin-based resin is commercially available as various products. Specific examples thereof include products available under the product names “ZEONEX” and “ZEONOR” from Zeon Corporation, a product available under the product name “Arton” from JSR Corporation, a product available under the product name “TOPAS” from TICONA, and a product available under the product name “APEL” from Mitsui Chemicals, Inc.

The film for forming the retardation layer may be of a sheet shape, or may be of an elongate shape. In one embodiment, the retardation layer is produced by cutting out the resin film, which has been stretched in its elongate direction, in a direction at a predetermined angle with respect to the elongate direction. In another embodiment, the retardation layer is produced by continuously subjecting the resin film of an elongate shape to oblique stretching in the direction at the predetermined angle with respect to its elongate direction. In still another embodiment, the retardation layer is produced by: obliquely stretching a laminate of a supporting substrate and a resin layer laminated on the supporting substrate; and transferring the obliquely stretched resin layer (resin film) onto any other layer. When the oblique stretching is adopted, a stretched film of an elongate shape having an alignment angle that is the predetermined angle with respect to the elongate direction of the film (having a slow axis in the direction at the angle) is obtained, and for example, roll-to-roll operation can be performed in its lamination with the other layer. Accordingly, a production process for the retardation layer can be simplified. The predetermined angle may be an angle formed by the absorption axis (elongate direction) of the polarizer and the slow axis of the retardation layer.

E-3. Retardation Layers of Third Embodiment

In this embodiment, as described above, the in-plane retardation Re(550) of the first retardation layer is preferably from 120 nm to 160 nm, and the refractive index ellipsoid of the second retardation layer satisfies a relationship of nz>nx=ny.

E-3-1. First Retardation Layer

When the first retardation layer of this embodiment contains the liquid crystal compound, the layer may be formed by using, for example, the material and the method described in the section E-1. When the first retardation layer is free of any liquid crystal compound, the layer may be formed by using the material and the method described in the section E-2-3.

E-3-2. Second Retardation Layer

As described above, the refractive index ellipsoid of the second retardation layer of this embodiment satisfies a relationship of nz>nx=ny. The second retardation layer typically shows such a reverse wavelength dispersion characteristic that its in-plane retardation value increases as the wavelength of measurement light increases. In this case, the ratio “Re (450)/Re (550)” of the second retardation layer is preferably 0.8 or more and less than 1, more preferably 0.8 or more and 0.95 or less.

The second retardation layer may include any appropriate liquid crystal compound as long as the above-mentioned optical characteristics can be satisfied. Details about such liquid crystal compound are described in JP 4186980 B2 and JP 6055569 B1, the description of which is incorporated herein by reference. In one embodiment, the second retardation layer may include a side chain-type liquid crystal polymer represented by the following chemical formula (I) (numbers 65 and 35 in the formula each represent the mol % of a monomer unit, and the polymer is represented in a block polymer body for convenience: weight-average molecular weight: 5,000) and a polymerizable liquid crystal showing a nematic liquid crystal phase.

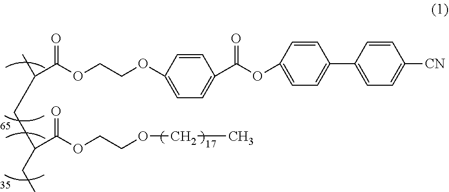

F. Organic EL Display Apparatus

The optical laminate described in the sections A to E may be used in an image display apparatus. Therefore, the present invention also encompasses an image display apparatus using such optical laminate. Typical examples of the image display apparatus include a liquid crystal display apparatus and an organic electroluminescence (EL) display apparatus. The image display apparatus (organic EL display apparatus) according to an embodiment of the present invention includes the optical laminate described in the sections A to E.

### EXAMPLES

Now, the present invention is specifically described by way of Examples. However, the present invention is not limited by these Examples. Measurement methods for characteristics are as described below.

(1) Thickness

Measurement was performed with a dial gauge (manufactured by PEACOCK, product name: “DG-205”, including a dial gauge stand (product name: “pds-2”)).

### (2) Retardation

Measurement was performed with AxoScan (manufactured by Axometrics, Inc.). A measurement temperature was set to 23° C., and a measurement wavelength was set to 550 nm.

### (3) Measurement of Transmittance of Pressure-sensitive Adhesive Layer

The release films of pressure-sensitive adhesive layers obtained in Examples and Comparative Examples were peeled, and each of the pressure-sensitive adhesive layers was bonded to a measurement jig, followed by the measurement of its transmittance with a spectrophotometer (product name: U-4100, manufactured by Hitachi High-Technologies Corporation). The transmittance was measured in the wavelength range of from 300 nm to 780 nm.

(4) Measurement of Transmittance of Film with Pressure-Sensitive Adhesive Layer

The release films of films with pressure-sensitive adhesive layers obtained in Examples and Comparative Examples were peeled, and the transmittance of each of the films with pressure-sensitive adhesive layers was measured with a spectrophotometer (product name: U-4100, manufactured by Hitachi High-Technologies Corporation). The transmittance was measured in the wavelength range of from 350 nm to 780 nm.

### (5) Adhesive Property

A sheet piece having a length of 100 mm and a width of 20 mm was cut out of each of the pressure-sensitive adhesive layers obtained in Examples and Comparative Examples. Next, one release film of the pressure-sensitive adhesive layer was peeled, and a PET film (product name: LUMIRROR S-10, thickness: 25 pm, manufactured by Toray Industries, Inc.) was bonded to the remainder (to back the remainder). Next, the other release film was peeled, and the remainder was crimped onto a glass plate (product name: SODA-LIME GLASS #0050, manufactured by Matsunami Glass Ind., Ltd.) serving as a test plate under the following crimping conditions: a 2-kilogram roller was reciprocated once. Thus, a sample having the configuration “test plate/pressure-sensitive adhesive layer (A)/PET film” was produced. The resultant sample was treated with an autoclave (at 50° C. and 0.5 MPa for 15 minutes), and was then left standing to cool under an atmosphere at 23° C. and 50% R.H. for 30 minutes. After the cooling, the pressure-sensitive adhesive sheet (pressure-sensitive adhesive layer/PET film) was peeled from the test plate with a tensile tester (apparatus name: AUTOGRAPH AG-IS, manufactured by Shimadzu Corporation) in conformity with JIS Z 0237 under an atmosphere at 23° C. and 50% R.H., and under the conditions of a tensile rate of 300 mm/min and a peel angle of 180°, and a 180° peeling adhesive strength (N/20 mm) was measured.

### (6) Total Light Transmittance and Haze

One release film was peeled from each of the pressure-sensitive adhesive layers obtained in Examples and Comparative Examples, and the remainder was bonded to slide glass (product name: WHITE EDGE GRINDING No. 1, thickness: from 0.8 mm to 1.0 mm, total light transmittance: 92%, haze: 0.2%, manufactured by Matsunami Glass Ind., Ltd.). Further, the other release film was peeled. Thus, a test piece having the layer configuration “pressure-sensitive adhesive layer (A)/slide glass” was produced. The total light transmittance and haze value of the test piece in a visible light region were measured with a haze meter (apparatus name: HM-150, manufactured by Murakami Color Research Laboratory Co., Ltd.).

### (7) Light Fastness Test

Each of optical laminates obtained in Examples and Comparative Examples was loaded into a xenon weatherometer (apparatus name: ATLAS Ci4000, manufactured by DJK Corporation) with its viewer side placed on a light source side under such a condition that an output at a wavelength of 420 nm was set to 0.8 W for 300 hours, followed by the measurement of a change ratio between the retardation values of its retardation layer before and after the test.

### Production Example 1

### (Production of Polarizer)

An amorphous polyethylene terephthalate (A-PET) film (manufactured by Mitsubishi Plastics, Inc., product name: “NOVACLEAR”, thickness: 100 μm) was used as a resin substrate. An aqueous solution of a polyvinyl alcohol (PVA) resin (manufactured by the Nippon Synthetic Chemical Industry Co., Ltd., product name: “GOHSENOL (trademark) NH-26”) was applied to one surface of the resin substrate and dried at 60° C. to form a PVA-based resin layer having a thickness of 7 μm. The laminate thus obtained was immersed in an insolubilizing bath having a liquid temperature of 30° C. (aqueous solution of boric acid obtained by compounding 100 parts by weight of water with 4 parts by weight of boric acid) for 30 seconds (insolubilizing step). Next, the laminate was immersed in a dyeing bath having a liquid temperature of 30° C. (aqueous solution of iodine obtained by compounding 100 parts by weight of water with 0.2 part by weight of iodine, and compounding the resultant with 2 parts by weight of potassium iodide) for 60 seconds (dyeing step). Next, the laminate was immersed in a cross-linking bath having a liquid temperature of 30° C. (aqueous solution of boric acid obtained by compounding 100 parts by weight of water with 3 parts by weight of potassium iodide, and compounding the resultant with 3 parts by weight of boric acid) for 30 seconds (cross-linking step). After that, the laminate was uniaxially stretched in its longitudinal direction (lengthwise direction) between rolls having different peripheral speeds while being immersed in an aqueous solution of boric acid having a liquid temperature of 60° C. (aqueous solution obtained by compounding 100 parts by weight of water with 4 parts by weight of boric acid, and compounding the resultant with 5 parts by weight of potassium iodide). The time period for which the laminate was immersed in the aqueous solution of boric acid was 120 seconds, and the laminate was stretched until immediately before its rupture. After that, the laminate was immersed in a washing bath (aqueous solution obtained by compounding 100 parts by weight of water with 3 parts by weight of potassium iodide), and was then dried with warm air at 60° C. (washing-drying step). Thus, a laminate in which a polarizer having a thickness of 5 μm was formed on the resin substrate was obtained. Next, the resin substrate was peeled from the polarizer, and an acrylic transparent protective film described in JP 2012-3269 A was bonded as a protective film to one surface of the polarizer. Thus, a polarizer with a protective film was obtained. The polarizer with a protective film was subjected to corona treatment before its use.

### Production Example 2

(Production of Adhesive A for forming Adhesive Layer)

50 Parts of PLACCEL FA1DDM (manufactured by Daicel Corporation), 40 parts of acryloylmorpholine (ACMO: trademark) (manufactured by Kohj in Co., Ltd.), 10 parts of ARFONUP-1190 (manufactured by Toagosei Co., Ltd.), 3 parts of a photopolymerization initiator (product name: “KAYACURE DETX-S”, manufactured by Nippon Kayaku Co., Ltd.), and 3 parts of IRGACURE 907 (manufactured by BASF Japan Ltd.) were mixed to prepare an adhesive A.

### Production Example 3

### (Production of Pressure-sensitive Adhesive Layer B)

95 Parts by weight of butyl acrylate, 5 parts by weight of acrylic acid, 0.2 part by weight of azobisisobutyronitrile serving as a polymerization initiator, and 233 parts by weight of ethyl acetate were loaded into a separable flask including a temperature gauge, a stirring machine, a reflux condenser, and a nitrogen gas-introducing tube. After that, a nitrogen gas was flowed to purge air in the flask with nitrogen for about 1 hour while the mixture was stirred. After that, the flask was heated to 60° C., and the mixture was subjected to a reaction for 7 hours to provide an acrylic polymer having a weight-average molecular weight (Mw) of 1,100,000.

0.8 Part by weight of trimethylolpropane tolylene diisocyanate (product name: CORONATE L, manufactured by Nippon Polyurethane Industry Co., Ltd.) serving as an isocyanate-based cross-linking agent and 0.1 part by weight of a silane coupling agent (product name: KBM-403, manufactured by Shin-Etsu Chemical Co., Ltd.) were added to a solution of the acrylic polymer (whose solid content was set to 100 parts by weight) to prepare a pressure-sensitive adhesive composition (b) (solution).

The resultant solution of the pressure-sensitive adhesive composition (b) was applied onto a separator having a thickness of 38 μm (polyethylene terephthalate-based film whose surface had been subjected to release treatment) so that its thickness after drying became 23 μm. The solution was dried at 100° C. for 3 minutes so that its solvent was removed. Thus, a pressure-sensitive adhesive layer was obtained. After that, the layer was heated at 50° C. for hours to be subjected to cross-linking treatment. The pressure-sensitive adhesive layer is hereinafter referred to as “pressure-sensitive adhesive layer (B)”.

### Production Example 4

(Production of Retardation Film A for forming Retardation Layer)

A transparent resin substrate formed of cellulose acylate was subjected to alkali saponification treatment. Next, an alignment film application liquid was applied to the surface of the cellulose acylate subjected to the alkali saponification treatment, and was dried to be subjected to λ/2 alignment treatment. Next, an application liquid containing a discotic liquid crystalline compound was applied to the alignment-treated surface of the transparent resin substrate, and was heated and irradiated with UV light so that the alignment of the discotic liquid crystalline compound was fixed. Thus, a retardation film A having a thickness of 2 μm was produced on the transparent resin substrate. The retardation film A had an in-plane retardation Re(550) of 246 nm. The resultant retardation film A was subjected to corona treatment before its use.

### Production Example 5

(Production of Retardation Film B for forming Retardation Layer)

An application liquid containing a rod-shaped and polymerizable nematic liquid crystal monomer was applied to a transparent resin substrate for A/4 alignment obtained by subjecting an alignment film to rubbing treatment, and was fixed under a state in which its refractive index anisotropy was held. Thus, a retardation film B having a thickness of 1 μm was produced on the transparent resin substrate. The retardation film B had an in-plane retardation Re(550) of 120 nm. The resultant retardation film B was subjected to corona treatment before its use.

### Production Example 6

(Production of Retardation Film C for forming Retardation Layer)

20 Parts by weight of the side chain-type liquid crystal polymer represented by the chemical formula (I) described in the section E-3-2, 80 parts by weight of a polymerizable liquid crystal compound showing a nematic liquid crystal phase (manufactured by BASF SE: product name: Paliocolor LC242), and 5 parts by weight of a photopolymerization initiator (manufactured by Ciba Specialty Chemicals: product name: IRGACURE 907) were dissolved in 200 parts by weight of cyclopentanone. Thus, a liquid crystal application liquid was prepared. Then, the application liquid was applied to a substrate film (norbornene-based resin film: manufactured by Zeon Corporation, product name: “ZEONEX”) with a bar coater, and was then heated and dried at 80° C. for 4 minutes so that the liquid crystal was aligned. UV light was applied to the liquid crystal layer to cure the liquid crystal layer. Thus, a liquid crystal fixed layer (thickness: 0.58 μm) serving as a retardation film C was formed on the substrate. The layer had an Re (550) of 0 nm and an Rth (550) of −71 nm (nx: 1.5326, ny: 1.5326, nz: 1.6550), and showed a refractive index characteristic of nz>nx=ny.

### Example 1

### 1. Production of UV-absorbing Adhesion Layer

### 1-1. Production of Base Polymer

A monomer mixture including 78 parts by weight of 2 -ethylhexyl acrylate (2EHA), 18 parts by weight of N-vinyl-2-pyrrolidone (NVP), and 15 parts by weight of 2-hydroxyethyl acrylate (HEA)was compounded with 0.035 part by weight of 1-hydroxycyclohexyl phenyl ketone (product name: IRGACURE 184, having an absorption band in the wavelength range of from 200 nm to 370 nm, manufactured by BASF SE) and 0.035 part by weight of 2,2-dimethoxy-1,2-diphenylethan-1-one (product name: IRGACURE 651, having an absorption band in the wavelength range of from 200 nm to 380 nm, manufactured by BASF SE) serving as photopolymerization initiators. After that, the resultant was irradiated with UV light until its viscosity (measurement conditions: a BH viscometer, a No. 5 rotor, 10 rpm, and a measurement temperature of 30° C.) became about 20 Pa·s. Thus, a prepolymer composition (polymerization ratio: 8%) in which part of the monomer components polymerized was obtained. Next, 0.15 part by weight of hexanediol diacrylate (HDDA) and 0.3 part by weight of a silane coupling agent (product name: KBM-403, manufactured by Shin-Etsu Chemical Co., Ltd.) were added to and mixed in the prepolymer composition. Thus, an acrylic pressure-sensitive adhesive composition (a) was obtained.

### 1-2. Production of UV-absorbing Adhesion Layer Composition (A)

0.7 Part by weight (solid content weight) of 2,4-bis-[{4-(4-ethylhexyloxy)-4-hydroxy}-phenyl]-6-(4-methoxyphenyl)-1,3,5-triazine (product name: Tinosorb S, “UV absorber (b1)” in Table 1, maximum absorption wavelength of its absorption spectrum: 346 nm, manufactured by BASF Japan Ltd.) dissolved in butyl acrylate so that its solid content became 15%, 0.3 part by weight of bis(2,4,6-trimethylbenzoyl)-phenylphosphine oxide (product name: IRGACURE 819, having an absorption band in the wavelength range of from 200 nm to 450 nm, manufactured by BASF Japan Ltd.), and 0.5part by weight (solid content weight) of BONASORBUA-3911 (product name, indole-based compound, “dye compound (c1)” in Table 1, maximum absorption wavelength of its absorption spectrum: 398 nm, half-width: 48 nm, manufactured by Orient Chemical Industries Co., Ltd.) dissolved in N-vinyl-2-pyrrolidone (NVP) so that its solid content became 5% were added to the resultant acrylic pressure-sensitive adhesive composition (a), and the mixture was stirred to provide a UV-absorbing adhesion layer composition (A).

### 1-3. Production of Pressure-sensitive Adhesive Layer (A-1)

The UV-absorbing adhesion layer composition (A) was applied onto a release-treated surface of a release film so that its thickness after the formation of a pressure-sensitive adhesive layer became 150 μm. Next, another release film was bonded to the surface of the UV-absorbing adhesion layer composition. After that, UV irradiation was performed under the conditions of an illuminance of 6.5 mW/cm², a light quantity of 1, 500 mJ/cm², and a peak wavelength of 350 nm to optically cure the UV-absorbing adhesion layer composition. Thus, a pressure-sensitive adhesive layer (A-1) was formed.

### 2. Production of Optical Laminate

The adhesive A was applied to the polarizer side of the polarizer with a protective film described above, and the retardation film A for forming a first retardation layer was transferred from the transparent resin substrate onto the surface having applied thereto the adhesive A so that an angle formed by the absorption axis of the polarizer and the slow axis of the retardation film A became 15°, followed by UV irradiation (300 mJ/cm²) to cure the adhesive A.

Next, the adhesive A was applied to the surface of the retardation film A opposite to the polarizer, and the retardation film B for forming a second retardation layer was transferred from the transparent resin substrate onto the surface having applied thereto the adhesive A so that an angle formed by the absorption axis of the polarizer and the slow axis of the retardation film B became 75°, and an angle formed by the slow axis of the retardation film A and the slow axis of the retardation film B became 60°, followed by UV irradiation (300 mJ/cm²) to cure the adhesive A. Thus, a polarizing plate with retardation layers was obtained. The thicknesses of the cured adhesives A (a first adhesive layer and a second adhesive layer) were 1 μm.

The pressure-sensitive adhesive layer (A-1) was laminated on the transparent protective film side of the polarizing plate with retardation layers. The pressure-sensitive adhesive layer (B) was laminated on the retardation film B side of the polarizing plate with retardation layers to form an optical laminate. The resultant optical laminate has the configuration “pressure-sensitive adhesive layer (A-1)/polarizer with a protective film/adhesive A/retardation film A/adhesive A/retardation film B/pressure-sensitive adhesive layer (B)”. The resultant optical laminate was subjected to a light fastness test while its pressure-sensitive adhesive layer (A-1) side was placed on a light source side. The results of the light fastness test, and the characteristics of an adhesion layer having the maximum UV-absorbing ability out of the adhesion layers positioned on a viewer side with respect to the retardation films are shown in Table 1.

### Example 2

An optical laminate was produced in the same manner as in Example 1 except that: the pressure-sensitive adhesive layer (B) was used for the bonding of the polarizer and the retardation film A; and the pressure-sensitive adhesive layer (B) was used for the bonding of the retardation film A and the retardation film B.

The resultant optical laminate has the configuration “pressure-sensitive adhesive layer (A-1)/polarizer with a protective film/pressure-sensitive adhesive layer (B)/retardation film A/pressure-sensitive adhesive layer (B)/retardation film B/pressure-sensitive adhesive layer (B)”. The resultant optical laminate was subjected to a light fastness test while its pressure-sensitive adhesive layer (A-1) side was placed on a light source side. The results of the light fastness test, and the characteristics of an adhesion layer having the maximum UV-absorbing ability out of the adhesion layers positioned on a viewer side with respect to the retardation films are shown in Table 1.

### Example 3

### 1. Production of UV-absorbing Adhesion Layer

A pressure-sensitive adhesive layer (A-2) was formed in the same manner as in Example 1 except that: the kind of the dye compound was changed to 2.5 parts by weight (solid content weight) of BONASORB UA3912 (product name, indole-based compound, “dye compound (c2)” in Table 1, maximum absorption wavelength of its absorption spectrum: 386 nm, half-width: 53 nm, manufactured by Orient Chemical Industries Co., Ltd.) dissolved in N-vinyl-2-pyrrolidone (NVP) so that its solid content became 10%; and the resultant composition was applied so that its thickness after the formation of the pressure-sensitive adhesive layer became 100 μm.

### 2. Production of Optical Laminate

An optical laminate was formed in the same manner as in Example 1 except that the UV-absorbing adhesion layer to be laminated on the transparent protective film side of the polarizing plate with retardation layers was changed to the pressure-sensitive adhesive layer (A-2).

The resultant optical laminate has the configuration “pressure-sensitive adhesive layer (A-2)/polarizer with a protective film/adhesive A/retardation film A/adhesive A/retardation film B/pressure-sensitive adhesive layer (B)”. The resultant optical laminate was subjected to a light fastness test while its pressure-sensitive adhesive layer (A-2) side was placed on a light source side. The results of the light fastness test, and the characteristics of an adhesion layer having the maximum UV-absorbing ability out of the adhesion layers positioned on a viewer side with respect to the retardation films are shown in Table 1.

### Example 4

### 1. Production of UV-Absorbing Adhesion Layer

The kind of the UV absorber of Example 1 was changed to 2- (2H-benzotriazol-2-yl) -6- (1-methyl-1-phenylethyl) -4- (1,1,3,3-tetramethylbutyl)phenol (product name: Tinuvin 928, “UV absorber (b2)” in Table 1, maximum absorption wavelength of its absorption spectrum: 349 nm, manufactured by BASF Japan Ltd.) dissolved in butyl acrylate so that its solid content became 15%, and the addition amount thereof was set to 1.5 parts by weight (solid content weight). Further, the kind of the dye compound was changed to a cinnamic acid-based compound (sample name: SOM-5-0103, “dye compound (c3)” in Table 1, maximum absorption wavelength of its absorption spectrum: 416 nm, half-width: 50 nm, manufactured by Orient Chemical Industries Co., Ltd.), and 0.2 part by weight (solid content weight) thereof was directly added to the acrylic pressure-sensitive adhesive composition (a), followed by the application of the resultant composition so that its thickness after the formation of the pressure-sensitive adhesive layer became 100 μm. A pressure-sensitive adhesive layer (A-3) was formed in the same manner as in Example 1 except the foregoing.

### 2. Production of Optical Laminate

An optical laminate was formed in the same manner as in Example 1 except that the pressure-sensitive adhesive layer to be laminated on the transparent protective film side of the polarizing plate with retardation layers was changed to the pressure-sensitive adhesive layer (A-3).

The resultant optical laminate has the configuration “pressure-sensitive adhesive layer (A-3)/polarizer with a protective film/adhesive A/retardation film A/adhesive A/retardation film A/pressure-sensitive adhesive layer (B)”. The resultant optical laminate was subjected to a light fastness test while its pressure-sensitive adhesive layer (A-3) side was placed on a light source side. The results of the light fastness test, and the characteristics of an adhesion layer having the maximum UV-absorbing ability out of the adhesion layers positioned on a viewer side with respect to the retardation films are shown in Table 1.

### Example 5

### 1. Production of UV-Absorbing Adhesion Layer

A pressure-sensitive adhesive layer (A-4) was formed in the same manner as in Example 1 except that: the addition amount of the UV absorber (b1) of Example 1 was changed to 3.0 parts by weight (solid content weight) ; the kind of the dye compound was changed to 0.1 part by weight (solid content weight) of a porphyrin-based compound (sample name: FDB-001, “dye compound (c4)” in Table 1, maximum absorption wavelength of its absorption spectrum: 420 nm, half-width: 14 nm, manufactured by Yamada Chemical Co., Ltd.) dissolved in N-vinyl-2-pyrrolidone (NVP) so that its solid content became 1%; and the resultant composition was applied so that its thickness after the formation of the pressure-sensitive adhesive layer became 100 μm.

### 2. Production of Optical Laminate

An optical laminate was formed in the same manner as in Example 1 except that the pressure-sensitive adhesive layer to be laminated on the transparent protective film side of the polarizing plate with retardation layers was changed to the pressure-sensitive adhesive layer (A-4).

The resultant optical laminate has the configuration “pressure-sensitive adhesive layer (A-4)/polarizer with a protective film/adhesive A/retardation film A/adhesive A/retardation film B/pressure-sensitive adhesive layer (B)”. The resultant optical laminate was subjected to a light fastness test while its pressure-sensitive adhesive layer (A-4) side was placed on a light source side. The results of the light fastness test, and the characteristics of an adhesion layer having the maximum UV-absorbing ability out of the adhesion layers positioned on a viewer side with respect to the retardation films are shown in Table 1.

### Example 6

The adhesive A was applied to the polarizer side of the polarizer with a protective film described above, and the retardation film B for forming a retardation layer was transferred from the transparent resin substrate onto the surface having applied thereto the adhesive A so that an angle formed by the absorption axis of the polarizer and the slow axis of the retardation film B became 45°, followed by UV irradiation (300 mJ/cm²) to cure the adhesive A. Thus, a polarizing plate with a retardation layer was obtained. The thickness of the cured adhesive A (a first adhesive layer) was 1 μm.

The same pressure-sensitive adhesive layer (A-1) as that of Example 1 was laminated on the transparent protective film side of the polarizing plate with a retardation layer. The pressure-sensitive adhesive layer (B) was laminated on the retardation film B side of the polarizing plate with a retardation layer to form an optical laminate.

The resultant optical laminate has the configuration “pressure-sensitive adhesive layer (A-1)/polarizer with a protective film/adhesive A/retardation film B/pressure-sensitive adhesive layer (B)”. The resultant optical laminate was subjected to a light fastness test while its pressure-sensitive adhesive layer (A-1) side was placed on a light source side. The results of the light fastness test, and the characteristics of an adhesion layer having the maximum UV-absorbing ability out of the adhesion layers positioned on a viewer side with respect to the retardation film are shown in Table 1.

### Example 7

The adhesive A was applied to the polarizer side of the polarizer with a protective film described above, and the retardation film B for forming a first retardation layer was transferred from the transparent resin substrate onto the surface having applied thereto the adhesive A so that an angle formed by the absorption axis of the polarizer and the slow axis of the retardation film B became 45°, followed by UV irradiation (300 mJ/cm²) to cure the adhesive A. Next, the adhesive A was applied to the surface of the retardation film B opposite to the polarizer, and the retardation film C for forming a second retardation layer was transferred from the transparent resin substrate onto the surface having applied thereto the adhesive A, followed by UV irradiation (300 mJ/cm²) to cure the adhesive A. Thus, a polarizing plate with retardation layers was obtained. The thicknesses of the cured adhesives A (a first adhesive layer and a second adhesive layer) were 1 μm.

The same pressure-sensitive adhesive layer (A-1) as that of Example 1 was laminated on the transparent protective film side of the polarizing plate with retardation layers. The pressure-sensitive adhesive layer (B) was laminated on the retardation film C side of the polarizing plate with retardation layers to form an optical laminate. The resultant optical laminate has the configuration “pressure-sensitive adhesive layer (A-1)/polarizer with a protective film/adhesive A/retardation film B/adhesive A/retardation film C/pressure-sensitive adhesive layer (B)”. The resultant optical laminate was subjected to a light fastness test while its pressure-sensitive adhesive layer (A-1) side was placed on a light source side. The results of the light fastness test, and the characteristics of an adhesion layer having the maximum UV-absorbing ability out of the adhesion layers positioned on a viewer side with respect to the retardation films are shown in Table 1.

### Example 8

The same pressure-sensitive adhesive layer (A-1) as that of Example 1 was bonded to the polarizer side of the polarizer with a protective film described above, and the retardation film A for forming a first retardation layer was transferred from the transparent resin substrate onto the pressure-sensitive adhesive layer so that an angle formed by the absorption axis of the polarizer and the slow axis of the retardation film A became 15°. Next, the pressure-sensitive adhesive layer (B) was bonded to the surface of the retardation film A opposite to the polarizer, and the retardation film B for forming a second retardation layer was transferred from the transparent resin substrate onto the pressure-sensitive adhesive layer so that an angle formed by the absorption axis of the polarizer and the slow axis of the retardation film B became 75°, and an angle formed by the slow axis of the retardation film A and the slow axis of the retardation film B became 60°. Thus, a polarizing plate with retardation layers was obtained.

The pressure-sensitive adhesive layer (B) was laminated on the transparent protective film side of the polarizing plate with retardation layers. The pressure-sensitive adhesive layer (B) was laminated on the retardation film B side of the polarizing plate with retardation layers to form an optical laminate. The resultant optical laminate has the configuration “pressure-sensitive adhesive layer (B)/polarizer with a protective film/pressure-sensitive adhesive layer (A-1)/retardation film A/pressure-sensitive adhesive layer (B)/retardation film B/pressure-sensitive adhesive layer (B)”. The resultant optical laminate was subjected to a light fastness test while its pressure-sensitive adhesive layer (B) side in contact with the polarizer with a protective film was placed on a light source side. The results of the light fastness test, and the characteristics of an adhesion layer having the maximum UV-absorbing ability out of the adhesion layers positioned on a viewer side with respect to the retardation films are shown in Table 1.

### Comparative Example 1

A pressure-sensitive adhesive layer (A1-1) was formed in the same manner as in Example 1 except that in the pressure-sensitive adhesive layer (A-1) of Example 1, only the acrylic pressure-sensitive adhesive composition (a) that was free of both of the UV absorber (b1) and the dye compound (c1) was used.

An optical laminate was formed in the same manner as in Example 1 except that the pressure-sensitive adhesive layer to be laminated on the transparent protective film side of the polarizing plate with retardation layers of Example 1 was changed to the pressure-sensitive adhesive layer (A1-1). The resultant optical laminate has the configuration “pressure-sensitive adhesive layer (A1-1)/polarizer with a protective film/adhesive A/retardation film A/adhesive A/retardation film B/pressure-sensitive adhesive layer (B)”. The resultant optical laminate was subjected to a light fastness test while its pressure-sensitive adhesive layer (A1-1) side was placed on a light source side. The results of the light fastness test, and the characteristics of an adhesion layer having the maximum UV-absorbing ability out of the adhesion layers positioned on a viewer side with respect to the retardation films are shown in Table 1.

### Comparative Example 2

An optical laminate was formed in the same manner as in Example 2 except that the pressure-sensitive adhesive layer to be laminated on the transparent protective film side of the polarizing plate with retardation layers of Example 2 was changed to the pressure-sensitive adhesive layer (A1-1). The resultant optical laminate has the configuration “pressure-sensitive adhesive layer (A1-1)/polarizer with a protective film/pressure-sensitive adhesive layer (B)/retardation film A/pressure-sensitive adhesive layer (B)/retardation film B/pressure-sensitive adhesive layer (B)”. The resultant optical laminate was subjected to a light fastness test while its pressure-sensitive adhesive layer (A1-1) side was placed on a light source side. The results of the light fastness test, and the characteristics of an adhesion layer having the maximum UV-absorbing ability out of the adhesion layers positioned on a viewer side with respect to the retardation films are shown in Table 1.

### Comparative Example 3

An optical laminate was formed in the same manner as in Example 1 except that the pressure-sensitive adhesive layer to be laminated on the transparent protective film side of the polarizing plate with retardation layers of Example 1 was changed to the pressure-sensitive adhesive layer (B). The resultant optical laminate has the configuration “pressure-sensitive adhesive layer (B)/polarizer with a protective film/adhesive A/retardation film A/adhesive A/retardation film B/pressure-sensitive adhesive layer (B)”. The resultant optical laminate was subjected to a light fastness test while its pressure-sensitive adhesive layer (B) side in contact with the polarizer with a protective film was placed on a light source side. The results of the light fastness test, and the characteristics of an adhesion layer having the maximum UV-absorbing ability out of the adhesion layers positioned on a viewer side with respect to the retardation films are shown in Table 1.

### Comparative Example 4

A pressure-sensitive adhesive layer (A1-2) was formed in the same manner as in Example 1 except that in the pressure-sensitive adhesive layer (A-1) of Example 1, the dye compound (c1) was not incorporated into the acrylic pressure-sensitive adhesive composition (a), and the resultant composition was applied so that its thickness after the formation of the pressure-sensitive adhesive layer became 100 μm.

An optical laminate was formed in the same manner as in Example 1 except that the pressure-sensitive adhesive layer to be laminated on the transparent protective film side of the polarizing plate with retardation layers of Example 1 was changed to the pressure-sensitive adhesive layer (A1-2). The resultant optical laminate has the configuration “pressure-sensitive adhesive layer (A1-2)/polarizer with a protective film/adhesive A/retardation film A/adhesive A/retardation film B/pressure-sensitive adhesive layer (B)”. The resultant optical laminate was subjected to a light fastness test while its pressure-sensitive adhesive layer (A1-2) side was placed on a light source side. The results of the light fastness test, and the characteristics of an adhesion layer having the maximum UV-absorbing ability out of the adhesion layers positioned on a viewer side with respect to the retardation films are shown in Table 1.

### Comparative Example 5

A pressure-sensitive adhesive layer (A1-3) was formed in the same manner as in Example 4 except that in the pressure-sensitive adhesive layer (A-3) of Example 4, the dye compound (c3) was not incorporated into the acrylic pressure-sensitive adhesive composition (a), and the resultant composition was applied so that its thickness after the formation of the pressure-sensitive adhesive layer became 150 μm.

An optical laminate was formed in the same manner as in Example 1 except that the pressure-sensitive adhesive layer to be laminated on the transparent protective film side of the polarizing plate with retardation layers of Example 1 was changed to the pressure-sensitive adhesive layer (A1-3). The resultant optical laminate has the configuration “pressure-sensitive adhesive layer (A1-3)/polarizer with a protective film/adhesive A/retardation film A/adhesive A/retardation film B/pressure-sensitive adhesive layer (B)”. The resultant optical laminate was subjected to a light fastness test while its pressure-sensitive adhesive layer (A1-3) side was placed on a light source side. The results of the light fastness test, and the characteristics of an adhesion layer having the maximum UV-absorbing ability out of the adhesion layers positioned on a viewer side with respect to the retardation films are shown in Table 1.

### Comparative Example 6

A pressure-sensitive adhesive layer (A1-4) was formed in the same manner as in Example 1 except that in the pressure-sensitive adhesive layer (A-1) of Example 1, the UV absorber (b1) was not incorporated into the acrylic pressure-sensitive adhesive composition (a), the addition amount of the dye compound (c1) was set to 0.3 part by weight (solid content weight), and the resultant composition was applied so that its thickness after the formation of the pressure-sensitive adhesive layer became 100 μm.

An optical laminate was formed in the same manner as in Example 1 except that the pressure-sensitive adhesive layer to be laminated on the transparent protective film side of the polarizing plate with retardation layers of Example 1 was changed to the pressure-sensitive adhesive layer (A1-4). The resultant optical laminate has the configuration “pressure-sensitive adhesive layer (A1-4)/polarizer with a protective film/adhesive A/retardation film A/adhesive A/retardation film B/pressure-sensitive adhesive layer (B)”. The resultant optical laminate was subjected to a light fastness test while its pressure-sensitive adhesive layer (A1-4) side was placed on a light source side. The results of the light fastness test, and the characteristics of an adhesion layer having the maximum UV-absorbing ability out of the adhesion layers positioned on a viewer side with respect to the retardation films are shown in Table 1.

### Comparative Example 7

A pressure-sensitive adhesive layer (A1-5) was formed in the same manner as in Example 3 except that in the pressure-sensitive adhesive layer (A-2) of Example 3, the UV absorber (b1) was not incorporated into the acrylic pressure-sensitive adhesive composition (a), and the addition amount of the dye compound (c2) was set to 0.5 part by weight (solid content weight).

An optical laminate was formed in the same manner as in Example 1 except that the pressure-sensitive adhesive layer to be laminated on the transparent protective film side of the polarizing plate with retardation layers of Example 1 was changed to the pressure-sensitive adhesive layer (A1-5). The resultant optical laminate has the configuration “pressure-sensitive adhesive layer (A1-5)/polarizer with a protective film/adhesive A/retardation film A/adhesive A/retardation film B/pressure-sensitive adhesive layer (B)”. The resultant optical laminate was subjected to a light fastness test while its pressure-sensitive adhesive layer (A1-5) side was placed on a light source side. The results of the light fastness test, and the characteristics of an adhesion layer having the maximum UV-absorbing ability out of the adhesion layers positioned on a viewer side with respect to the retardation films are shown in Table 1.

### Comparative Example 8

A pressure-sensitive adhesive layer (A1-6) was formed in the same manner as in Example 4 except that in the pressure-sensitive adhesive layer (A-3) of Example 4, the UV absorber (b2) was not incorporated into the acrylic pressure-sensitive adhesive composition (a).

An optical laminate was formed in the same manner as in Example 1 except that the pressure-sensitive adhesive layer to be laminated on the transparent protective film side of the polarizing plate with retardation layers of Example 1 was changed to the pressure-sensitive adhesive layer (A1-6). The resultant optical laminate has the configuration “pressure-sensitive adhesive layer (A1-6)/polarizer with a protective film/adhesive A/retardation film A/adhesive A/retardation film B/pressure-sensitive adhesive layer (B)”. The resultant optical laminate was subjected to a light fastness test while its pressure-sensitive adhesive layer (A1-6) side was placed on a light source side. The results of the light fastness test, and the characteristics of an adhesion layer having the maximum UV-absorbing ability out of the adhesion layers positioned on a viewer side with respect to the retardation films are shown in Table 1.

### Comparative Example 9

A pressure-sensitive adhesive layer (A1-7) was formed in the same manner as in Example 5 except that in the pressure-sensitive adhesive layer (A-4) of Example 5, the UV absorber (b1) was not incorporated into the acrylic pressure-sensitive adhesive composition (a).

An optical laminate was formed in the same manner as in Example 1 except that the pressure-sensitive adhesive layer to be laminated on the transparent protective film side of the polarizing plate with retardation layers of Example 1 was changed to the pressure-sensitive adhesive layer (A1-7). The resultant optical laminate has the configuration “pressure-sensitive adhesive layer (A1-7)/polarizer with a protective film/adhesive A/retardation film A/adhesive A/retardation film B/pressure-sensitive adhesive layer (B)”. The resultant optical laminate was subjected to a light fastness test while its pressure-sensitive adhesive layer (A1-7) side was placed on a light source side. The results of the light fastness test, and the characteristics of an adhesion layer having the maximum UV-absorbing ability out of the adhesion layers positioned on a viewer side with respect to the retardation films are shown in Table 1.

### Comparative Example 10

An optical laminate was formed in the same manner as in Example except that in the optical laminate of Example 6, the pressure-sensitive adhesive layer to be laminated on the transparent protective film side of the polarizing plate with a retardation layer was changed to the pressure-sensitive adhesive layer (A1-1). The resultant optical laminate has the configuration “pressure-sensitive adhesive layer (A1-1)/polarizer with a protective film/adhesive A/retardation film B/pressure-sensitive adhesive layer (B)”. The resultant optical laminate was subjected to a light fastness test while its pressure-sensitive adhesive layer (A1-1) side was placed on a light source side. The results of the light fastness test, and the characteristics of an adhesion layer having the maximum UV-absorbing ability out of the adhesion layers positioned on a viewer side with respect to the retardation film are shown in Table 1.

### Comparative Example 11

An optical laminate was formed in the same manner as in Example except that in the optical laminate of Example 7, the pressure-sensitive adhesive layer to be laminated on the transparent protective film side of the polarizing plate with retardation layers was changed to the pressure-sensitive adhesive layer (A1-1). The resultant optical laminate has the configuration “pressure-sensitive adhesive layer (A1-1)/polarizer with a protective film/adhesive A/retardation film B/adhesive A/retardation film C/pressure-sensitive adhesive layer (B)”. The resultant optical laminate was subjected to a light fastness test while its pressure-sensitive adhesive layer A1-1 side was placed on a light source side. The results of the light fastness test, and the characteristics of an adhesion layer having the maximum UV-absorbing ability out of the adhesion layers positioned on a viewer side with respect to the retardation films are shown in Table 1.

### Comparative Example 12

An optical laminate was formed in the same manner as in Example except that in the optical laminate of Example 1, the pressure-sensitive adhesive layer to be laminated on the transparent protective film side of the polarizing plate with retardation layers was changed to the pressure-sensitive adhesive layer (B), and the pressure-sensitive adhesive layer to be laminated on the retardation film B side thereof was changed to the pressure-sensitive adhesive layer (A-1). The resultant optical laminate has the configuration “pressure-sensitive adhesive layer (B)/polarizer with a protective film/adhesive A/retardation film A/adhesive A/retardation film B/pressure-sensitive adhesive layer (A-1)”. The resultant optical laminate was subjected to a light fastness test while its pressure-sensitive adhesive layer (B) side in contact with the polarizer with a protective film was placed on a light source side. The results of the light fastness test, and the characteristics of an adhesion layer having the maximum UV-absorbing ability out of the adhesion layers positioned on a viewer side with respect to the retardation films are shown in Table 1.

TABLE 1

| | Adhesion layer having maximum UV-absorbing ability | | | | | | | | |
|---|---|---|---|---|---|---|---|---|---|
| | | | | | | | | Optical characteristic | |
| | | | | | | | | Average transmittance (%) | |
| | | | UV absorber (b) | | Dye compound (c) | | | 300 | 400 |
| | Kind of | | | Addition | | Addition | | nm to | nm to |
| | adhesion | Base | | amount | | amount | Thickness | 400 | 430 |
| | layer | polymer | Kind | (part(s)) | Kind | (part(s)) | (μm) | nm | nm |
| Example 1 | A-1 | (a) | b1 | 0.7 | c1 | 0.5 | 150 | 0.1 | 12.5 |
| Example 2 | A-1 | (a) | b1 | 0.7 | c1 | 0.5 | 150 | 0.1 | 12.5 |
| Example 3 | A-2 | (a) | b1 | 0.7 | c2 | 2.5 | 100 | 0.0 | 4.5 |
| Example 4 | A-3 | (a) | b2 | 1.5 | c3 | 0.2 | 100 | 0.7 | 0.9 |
| Example 5 | A-4 | (a) | b1 | 3.0 | c4 | 0.1 | 100 | 1.1 | 5.4 |
| Example 6 | A-1 | (a) | b1 | 0.7 | c1 | 0.5 | 150 | 0.1 | 12.5 |
| Example 7 | A-1 | (a) | b1 | 0.7 | c1 | 0.5 | 150 | 0.1 | 12.5 |
| Example 8 | A-1 | (a) | b1 | 0.7 | c1 | 0.5 | 150 | 0.1 | 12.5 |
| Comparative | A1-1 | (a) | — | — | — | — | 150 | 92.0 | 92.3 |
| Example 1 | | | | | | | | | |
| Comparative | A1-1 | (a) | — | — | — | — | 150 | 92.0 | 92.3 |
| Example 2 | | | | | | | | | |
| Comparative | B | (b) | — | — | — | — | 23 | 91.0 | 92.3 |
| Example 3 | | | | | | | | | |
| Comparative | A1-2 | (a) | b1 | 0.7 | — | — | 100 | 8.7 | 86.4 |
| Example 4 | | | | | | | | | |
| Comparative | A1-3 | (a) | b2 | 1.5 | — | — | 150 | 6.7 | 86.5 |
| Example 5 | | | | | | | | | |
| Comparative | A1-4 | (a) | — | — | c1 | 0.3 | 100 | 21.1 | 26.3 |
| Example 6 | | | | | | | | | |
| Comparative | A1-5 | (a) | — | — | c2 | 0.5 | 100 | 11.3 | 34.2 |
| Example 7 | | | | | | | | | |
| Comparative | A1-6 | (a) | — | — | c3 | 0.2 | 100 | 53.0 | 0.8 |
| Example 8 | | | | | | | | | |
| Comparative | A1-7 | (a) | — | — | c4 | 0.1 | 100 | 82.9 | 17.5 |
| Example 9 | | | | | | | | | |
| Comparative | A1-1 | (a) | — | — | — | — | 150 | 92.0 | 92.3 |
| Example 10 | | | | | | | | | |
| Comparative | A1-1 | (a) | — | — | — | — | 150 | 92.0 | 92.3 |
| Example 11 | | | | | | | | | |
| Comparative | B | (b) | — | — | — | — | 23 | 91.0 | 92.3 |
| Example 12 | | | | | | | | | |

| | Adhesion layer having maximum UV-absorbing ability | | | | | | | |
|---|---|---|---|---|---|---|---|---|
| | Optical characteristic | | | | | | Light fastness | |
| | Average transmittance (%) | | | | | | test result | |
| | 430 | 450 | 500 | Total | | Adhesive | Change ratio of | |
| | nm to | nm to | nm to | light | Haze | strength | Re(550) (%) | |
| | 450 | 500 | 780 | transmittance | value | [N/20 | Retardation | Retardation |
| | nm | nm | nm | (%) | (%) | mm] | film A | film B |
| Example 1 | 76.9 | 91.5 | 92.4 | 92.3 | 0.4 | 12.0 | −2.9 | −0.7 |
| Example 2 | 76.9 | 91.5 | 92.4 | 92.3 | 0.4 | 12.0 | −2.8 | −0.8 |
| Example 3 | 60.0 | 89.5 | 91.4 | 92.3 | 0.4 | 9.0 | −2.1 | −0.5 |
| Example 4 | 7.0 | 74.8 | 91.9 | 92.3 | 0.4 | 13.0 | −2.2 | −0.5 |
| Example 5 | 51.3 | 82.7 | 84.9 | 77.6 | 0.6 | 10.0 | −2.5 | −0.6 |
| Example 6 | 76.9 | 91.5 | 92.4 | 92.3 | 0.4 | 12.0 | — | −0.7 |
| Example 7 | 76.9 | 91.5 | 92.4 | 92.3 | 0.4 | 12.0 | — | −0.6 |
| Example 8 | 76.9 | 91.5 | 92.4 | 92.3 | 0.4 | 12.0 | −2.7 | −0.6 |
| Comparative | 92.5 | 92.5 | 92.9 | 92.4 | 0.3 | 14.0 | −8.8 | −5.4 |
| Example 1 | | | | | | | | |
| Comparative | 92.5 | 92.5 | 92.9 | 92.4 | 0.3 | 14.0 | −8.9 | −5.2 |
| Example 2 | | | | | | | | |
| Comparative | 92.5 | 92.5 | 92.9 | 92.6 | 0.3 | 7.0 | −7.6 | −5.0 |
| Example 3 | | | | | | | | |
| Comparative | 91.9 | 92.4 | 92.7 | 92.4 | 0.3 | 14.0 | −5.3 | −3.2 |
| Example 4 | | | | | | | | |
| Comparative | 92.0 | 92.4 | 92.7 | 92.3 | 0.3 | 14.0 | −4.7 | −3.1 |
| Example 5 | | | | | | | | |
| Comparative | 84.3 | 92.0 | 92.5 | 92.3 | 0.4 | 12.0 | −6.5 | −3.6 |
| Example 6 | | | | | | | | |
| Comparative | 89.3 | 92.9 | 93.0 | 92.3 | 0.4 | 10.0 | −6.0 | −3.2 |
| Example 7 | | | | | | | | |
| Comparative | 7.0 | 74.8 | 91.9 | 92.3 | 0.4 | 11.0 | −7.0 | −4.4 |
| Example 8 | | | | | | | | |
| Comparative | 51.3 | 82.7 | 84.9 | 92.3 | 0.4 | 11.0 | −7.2 | −4.4 |
| Example 9 | | | | | | | | |
| Comparative | 92.5 | 92.5 | 92.9 | 92.4 | 0.3 | 14.0 | — | −5.3 |
| Example 10 | | | | | | | | |
| Comparative | 92.5 | 92.5 | 92.9 | 92.4 | 0.3 | 14.0 | — | −5.4 |
| Example 11 | | | | | | | | |
| Comparative | 92.5 | 92.5 | 92.9 | 92.6 | 0.3 | 7.0 | −8.0 | −5.5 |
| Example 12 | | | | | | | | |

### INDUSTRIAL APPLICABILITY

The optical laminate of the present invention is suitably used in an image display apparatus, such as an organic EL display apparatus.

### REFERENCE SIGNS LIST

10 UV-absorbing adhesion layer

20 protective layer

21 first protective layer

22 second protective layer

30 polarizer

40 retardation layer

41 first retardation layer

42 second retardation layer

100 optical laminate

101 optical laminate

102 optical laminate

103 optical laminate

104 optical laminate

1. An optical laminate, comprising:
a UV-absorbing adhesion layer;
a protective layer;
a polarizer; and
a retardation layer,
wherein the retardation layer contains a liquid crystal compound,
wherein the UV-absorbing adhesion layer and the polarizer are arranged on a viewer side with respect to the retardation layer, and
wherein the UV-absorbing adhesion layer contains a base polymer, a UV absorber, and a dye compound whose absorption spectrum has a maximum absorption wavelength present in a wavelength region of from 380 nm to 430 nm.

2. The optical laminate according to claim 1, wherein the base polymer is a (meth)acrylic polymer.

3. The optical laminate according to claim 1, wherein an absorption spectrum of the UV absorber has a maximum absorption wavelength present in a wavelength region of from 300 nm to 400 nm.

4. The optical laminate according to claim 1, wherein the UV-absorbing adhesion layer has an average transmittance of 5% or less at a wavelength of from 300 nm to 400 nm, has an average transmittance of 30% or less at a wavelength of from 400 nm to 430 nm, has an average transmittance of 70% or more at a wavelength of from 450 nm to 500 nm, and has an average transmittance of 80% or more at a wavelength of from 500 nm to 780 nm.

5. The optical laminate according to claim 1, wherein the UV-absorbing adhesion layer, the protective layer, and the polarizer are arranged in the stated order.

6. The optical laminate according to claim 1, wherein the retardation layer has an in-plane retardation Re(550) of from 120 nm to 160 nm,
where Re(550) represents an in-plane retardation measured at 23° C. with light having a wavelength of 550 nm.

7. The optical laminate according to claim 1,
wherein the retardation layer includes a first retardation layer and a second retardation layer,
wherein at least one of the first retardation layer or the second retardation layer contains the liquid crystal compound, and
wherein the UV-absorbing adhesion layer is arranged on the viewer side with respect to the retardation layer containing the liquid crystal compound out of the first retardation layer and the second retardation layer.

8. The optical laminate according to claim 7, wherein the UV-absorbing adhesion layer, the protective layer, the polarizer, the first retardation layer, and the second retardation layer are arranged in the stated order from the viewer wide.

9. The optical laminate according to claim 7, wherein the UV-absorbing adhesion layer, the first protective layer, the polarizer, the second protective layer, the first retardation layer, and the second retardation layer are arranged in the stated order from the viewer wide.

10. The optical laminate according to claim 7, wherein the protective layer, the polarizer, the UV-absorbing adhesion layer, the first retardation layer, and the second retardation layer are arranged in the stated order from the viewer wide.

11. The optical laminate according to claim 7, wherein the first protective layer, the polarizer, the second protective layer, the UV-absorbing adhesion layer, the first retardation layer, and the second retardation layer are arranged in the stated order from the viewer wide.

12. The optical laminate according to claim 7, wherein the first retardation layer has an in-plane retardation Re(550) of from 240 nm to 320 nm,
where Re(550) represents an in-plane retardation measured at 23° C. with light having a wavelength of 550 nm.

13. The optical laminate according to claim 7, wherein the second retardation layer has an in-plane retardation Re(550) of from 120 nm to 160 nm,
where Re(550) represents an in-plane retardation measured at 23° C. with light having a wavelength of 550 nm.

14. An organic EL display apparatus, comprising the optical laminate of claim 1.

15. An optical laminate, comprising:
a UV-absorbing adhesion layer;
a protective layer;
a polarizer; and
a retardation layer,
wherein the retardation layer contains a liquid crystal compound,
wherein the UV-absorbing adhesion layer and the polarizer are arranged on a viewer side with respect to the retardation layer,
wherein the UV-absorbing adhesion layer contains a base polymer, a UV absorber, and a dye compound whose absorption spectrum has a maximum absorption wavelength present in a wavelength region of from 380 nm to 430 nm,
wherein the base polymer is a (meth)acrylic polymer including a monomer component selected from the group consisting of a branched alkyl (meth)acrylate having 4 to 9 carbon atoms, a cyclic nitrogen-containing monomer, a hydroxyl group-containing monomer and the combination thereof,
wherein the UV absorber is one selected from the group consisting of a triazine-based UV absorber, a benzotriazole-based UV absorber and the combination thereof, and
wherein the dye compound is one selected from the group consisting of an indole-based compound, a cinnamic acid-based compound, a porphyrin-based compound and the combination thereof.

16. The optical laminate according to claim 15, wherein the thickness of the UV-absorbing adhesion layer is from 100 μm to 150 μm.
